(19) United States
(12) Patent Application Publication
(10) Pub. No.: US 2025/0301643 A1
(43) Pub. Date: Sep. 25, 2025

(54) MEMORY DEVICE INCLUDING A CORE-SIDE CHARGE TRAPPING MATERIAL LAYER AND METHODS FOR FORMING THE SAME

(71) Applicant: SANDISK TECHNOLOGIES LLC, ADDISON, TX (US)

(72) Inventors: Takayuki GYAKUSHI, Yokkaichi (JP); Yukihiro SAKOTSUBO, Yokkaichi (JP); Takashi KUDO, Yokkaichi (JP); Liumin ZOU, Yokkaichi (JP); Kohei OSAWA, Yokkaichi (JP); Motoki MIZUTANI, Yokkaichi (JP)

(21) Appl. No.: 18/787,367

(22) Filed: Jul. 29, 2024

Related U.S. Application Data
(63) Continuation-in-part of application No. 18/615,516, filed on Mar. 25, 2024.

(51) Int. Cl. H10B 43/27; G11C 16/04; H10B 43/10; H10B 43/35

(52) U.S. Cl. CPC H10B 43/27; G11C 16/0483; H10B 43/10; H10B 43/35

(57) ABSTRACT

A memory device includes an alternating stack of insulating layers and electrically conductive layers, a memory opening vertically extending through the alternating stack, and a memory opening fill structure located in the memory opening. The memory opening fill structure includes, from outside to inside, a memory film, a vertical semiconductor channel, a core-side charge trapping material layer that vertically extends through at least a first subset of the electrically conductive layers, and a dielectric core.

### FIELD

The present disclosure relates generally to the field of semiconductor devices, and particularly to a memory device including a core-side charge trapping material layer and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device includes an alternating stack of insulating layers and electrically conductive layers, a memory opening vertically extending through the alternating stack, and a memory opening fill structure located in the memory opening. The memory opening fill structure includes, from outside to inside, a memory film, a vertical semiconductor channel, a core-side charge trapping material layer that vertically extends through at least a first subset of the electrically conductive layers, and a dielectric core.

According to another aspect of the present disclosure, a method of forming a memory device includes forming an alternating stack of insulating layers and spacer material layers over a substrate, wherein the spacer material layers are formed as or are subsequently replaced with electrically conductive layers; forming a memory opening through the alternating stack; forming a memory film, a vertical semiconductor channel, a core-side charge trapping material layer, and a primary dielectric core portion; reducing vertical extents of the primary dielectric core portion and the core-side charge trapping material layer; and forming a complementary dielectric core portion on the primary dielectric core portion within a volume that is laterally surrounded by a cylindrical segment of an inner sidewall of the vertical semiconductor channel in the memory opening.

According to an aspect of the present disclosure, a memory device is provided, which comprises: an alternating stack of insulating layers and electrically conductive layers; a memory opening vertically extending through the alternating stack; and a memory opening fill structure located in the memory opening and comprising, from outside to inside, a memory film containing a vertical stack of memory elements, a vertical semiconductor channel, and a core-side charge trapping material layer, and a dielectric core.

According to an aspect of the present disclosure, a method of operating a memory device comprising an alternating stack of insulating layers and electrically conductive layers; a memory opening vertically extending through the alternating stack; and a memory opening fill structure located in the memory opening and including, from outside to inside, a memory film containing a vertical stack of memory elements, a vertical semiconductor channel, a core-side charge trapping material layer, and a dielectric core, the method comprising applying an erase voltage to the memory device to move electrons from the memory film or from the electrically conductive layers through the vertical semiconductor channel into the core-side charge trapping material layer.

According to another aspect of the present disclosure, a method of forming a memory device comprises: forming an alternating stack of insulating layers and spacer material layers over a substrate, wherein the spacer material layers are formed as, or are subsequently replaced with, electrically conductive layers; forming a memory opening through the alternating stack; and forming a memory opening fill structure located in the memory opening by sequentially forming a memory film containing a vertical stack of memory elements, a vertical semiconductor channel, a core-side charge trapping material layer, and an as-deposited silicon oxide dielectric core in the memory opening.

### BRIEF DESCRIPTION OF THE DRAWINGS

FIG. 1 is a schematic vertical cross-sectional view of a first exemplary structure after formation of an alternating stack of insulating layers and sacrificial material layers over a carrier substrate according to an embodiment of the present disclosure.

FIG. 2 is a schematic vertical cross-sectional view of the first exemplary structure after formation of stepped surfaces and a stepped dielectric material portion according to an embodiment of the present disclosure.

FIG. 3A is a schematic vertical cross-sectional view of the first exemplary structure after formation of memory openings and support openings according to an embodiment of the present disclosure.

FIG. 3B is a top-down view of the first exemplary structure of FIG. 3A. The hinged vertical cross-sectional plane A-A′ is the cut plane of the vertical cross-sectional view of FIG. 3A.

FIG. 4 is a schematic vertical cross-sectional view of the first exemplary structure after formation of sacrificial opening fill structures according to an embodiment of the present disclosure.

FIG. 5 is a vertical cross-sectional view of the first exemplary structure after formation of support pillar structures according to an embodiment of the present disclosure.

FIG. 6 is a schematic vertical cross-sectional view of the first exemplary structure after removal of sacrificial memory opening fill structures according to an embodiment of the present disclosure.

FIGS. 7A-7H are sequential vertical cross-sectional views of a memory opening during formation of a memory opening fill structure having a first configuration according to an embodiment of the present disclosure.

FIGS. 8A and 8B are sequential vertical cross-sectional views of a memory opening during formation of a memory opening fill structure having a second configuration according to an embodiment of the present disclosure.

FIGS. 9A-9D are sequential vertical cross-sectional views of a memory opening during formation of a memory opening fill structure having a first configuration according to an embodiment of the present disclosure.

FIG. 9E is a vertical cross-sectional view of a memory opening fill structure having a fourth configuration according to an embodiment of the present disclosure.

FIG. 10A is a schematic vertical cross-sectional view of the first exemplary structure after formation of memory opening fill structures according to an embodiment of the present disclosure.

FIG. 10B is a top-down view of the first exemplary structure of FIG. 10A. The vertical plane A-A is the cut plane of the vertical cross-sectional view of FIG. 10A.

FIG. 11A is a vertical cross-sectional view of the first exemplary structure after formation of lateral isolation trenches according to an embodiment of the present disclosure.

FIG. 11B is a top-down view of the first exemplary structure of FIG. 11A. The vertical plane A-A is the cut plane of the vertical cross-sectional view of FIG. 11A.

FIG. 12 is a vertical cross-sectional view of the first exemplary structure after formation of laterally-extending cavities according to an embodiment of the present disclosure.

FIG. 13A is a schematic vertical cross-sectional view of the first exemplary structure after formation of electrically conductive layers according to an embodiment of the present disclosure.

FIG. 13B is a magnified vertical cross-sectional view of the first exemplary structure of FIG. 13A around a memory opening fill structure in case the memory opening fill structure has the first configuration.

FIG. 13C is a magnified vertical cross-sectional view of the first exemplary structure of FIG. 13A around a memory opening fill structure in case the memory opening fill structure has the second configuration.

FIG. 13D is a magnified vertical cross-sectional view of the first exemplary structure of FIG. 13A around a memory opening fill structure in case the memory opening fill structure has the third configuration.

FIG. 13E is a magnified vertical cross-sectional view of the first exemplary structure of FIG. 13A around a memory opening fill structure in case the memory opening fill structure has the fourth configuration.

FIG. 14A is a vertical cross-sectional view of the first exemplary structure after formation of lateral isolation trench fill structures and isolation trench fill structures according to an embodiment of the present disclosure.

FIG. 14B is a top-down view of the first exemplary structure of FIG. 14A. The vertical plane A-A is the cut plane of the vertical cross-sectional view of FIG. 14A.

FIG. 15A is a vertical cross-sectional view of the first exemplary structure after formation of layer contact via structures and drain contact via structures according to an embodiment of the present disclosure.

FIG. 15B is a top-down view of the first exemplary structure of FIG. 15A. The vertical plane A-A is the cut plane of the vertical cross-sectional view of FIG. 15A.

FIG. 16 is a vertical cross-sectional view of the first exemplary structure after formation of a memory die according to an embodiment of the present disclosure.

FIG. 17 is a vertical cross-sectional view of a logic die according to an embodiment of the present disclosure.

FIG. 18 is a vertical cross-sectional view of the first exemplary structure after attaching the logic die to the memory die according to an embodiment of the present disclosure.

FIG. 19 is a vertical cross-sectional view of the first exemplary structure after removal of the carrier substrate according to an embodiment of the present disclosure.

FIG. 20A is a vertical cross-sectional view of the first exemplary structure after formation of a source contact structure according to the first or the second embodiments of the present disclosure.

FIG. 20B is a magnified vertical cross-sectional view of the first exemplary structure of FIG. 20A around a memory opening fill structure in case the memory opening fill structure has the first configuration.

FIG. 20C is a magnified vertical cross-sectional view of the first exemplary structure of FIG. 20A around a memory opening fill structure in case the memory opening fill structure has the second configuration.

FIG. 20D is a magnified vertical cross-sectional view of the first exemplary structure of FIG. 20A around a memory opening fill structure in case the memory opening fill structure has the third configuration.

FIG. 20E is a magnified vertical cross-sectional view of the first exemplary structure of FIG. 20A around a memory opening fill structure in case the memory opening fill structure has the fourth configuration.

FIGS. 21A-21D are sequential vertical cross-sectional views of a memory opening in a second exemplary structure during formation of a memory opening fill structure in a first configuration according to an embodiment of the present disclosure.

FIG. 22 is a vertical cross-sectional view of a memory opening fill structure in the first configuration in the second exemplary structure after replacement of sacrificial material layers with electrically conductive layers according to an embodiment of the present disclosure.

FIG. 23 is a vertical cross-sectional views of a region around a memory opening in the second exemplary structure after formation of a memory opening fill structure in a second configuration according to an embodiment of the present disclosure.

FIG. 24 is a vertical cross-sectional view of a memory opening fill structure in the second configuration in the second exemplary structure after replacement of sacrificial material layers with electrically conductive layers according to an embodiment of the present disclosure.

FIG. 25 is a vertical cross-sectional views of a region around a memory opening in the second exemplary structure after formation of a memory opening fill structure in a third configuration according to an embodiment of the present disclosure.

FIG. 26 is a vertical cross-sectional view of a memory opening fill structure in the third configuration in the second exemplary structure after replacement of sacrificial material layers with electrically conductive layers according to an embodiment of the present disclosure.

FIG. 27 is a vertical cross-sectional view of a third exemplary structure after formation of an alternating stack of insulating layers and sacrificial material layers according to an embodiment of the present disclosure.

FIG. 28 is a vertical cross-sectional view of the third exemplary structure after formation of support pillar structures and memory opening fill structures according to an embodiment of the present disclosure.

FIG. 29A is a vertical cross-sectional view of the third exemplary structure after bonding a memory die with a logic die and after removing a carrier substrate according to an embodiment of the present disclosure.

FIG. 29B is a magnified view a region of the third exemplary structure of FIG. 29A.

FIGS. 30A-30G are sequential vertical cross-sectional views of a portion of a memory opening fill structure during modification of the memory opening fill structure according to an embodiment of the present disclosure.

FIG. 31 and FIG. 32 are vertical cross-sectional views of a portion of a memory opening fill structure in alternative configurations of the third exemplary structure according to an embodiment of the present disclosure.

### DETAILED DESCRIPTION

As discussed above, the embodiments of the present disclosure are directed to a memory device including a core-side charge trapping material layer and methods for forming the same, the various aspects of which are described below. Embodiments of the disclosure can be employed to form various structures including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layers thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

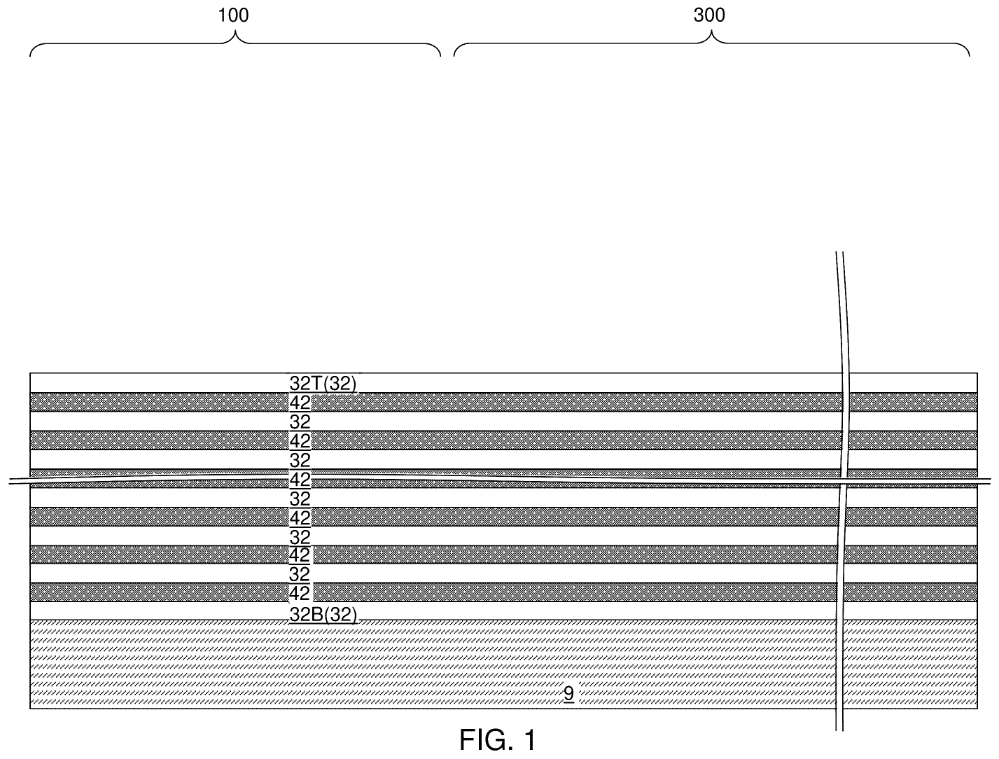

Referring to FIG. 1, a first exemplary structure according to an embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

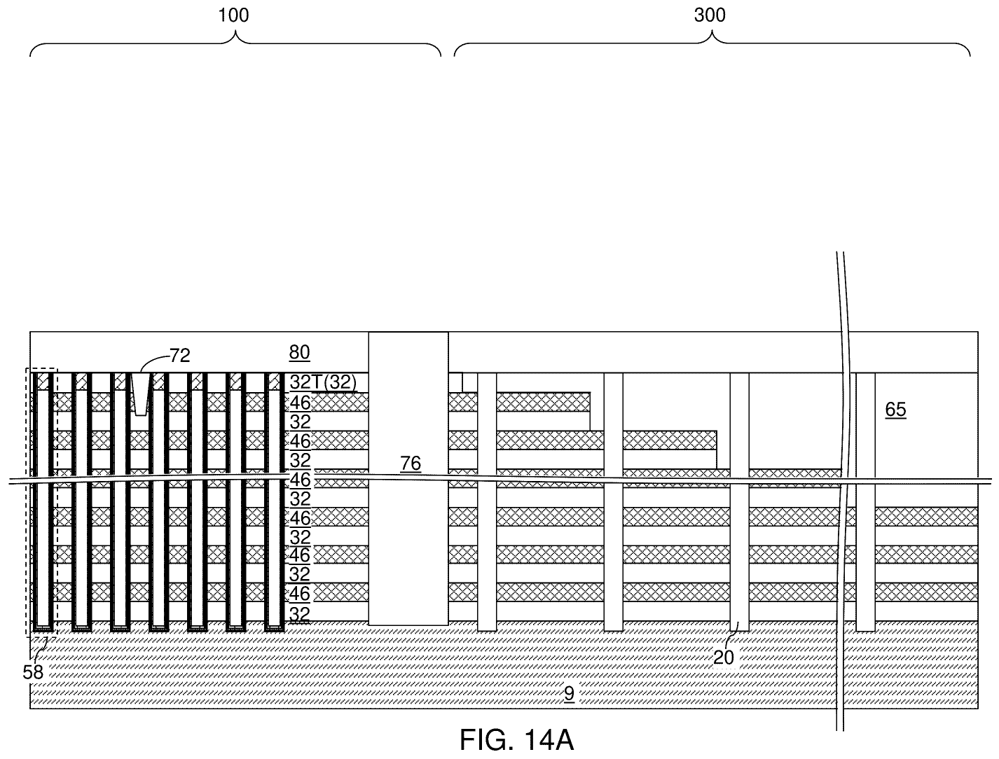

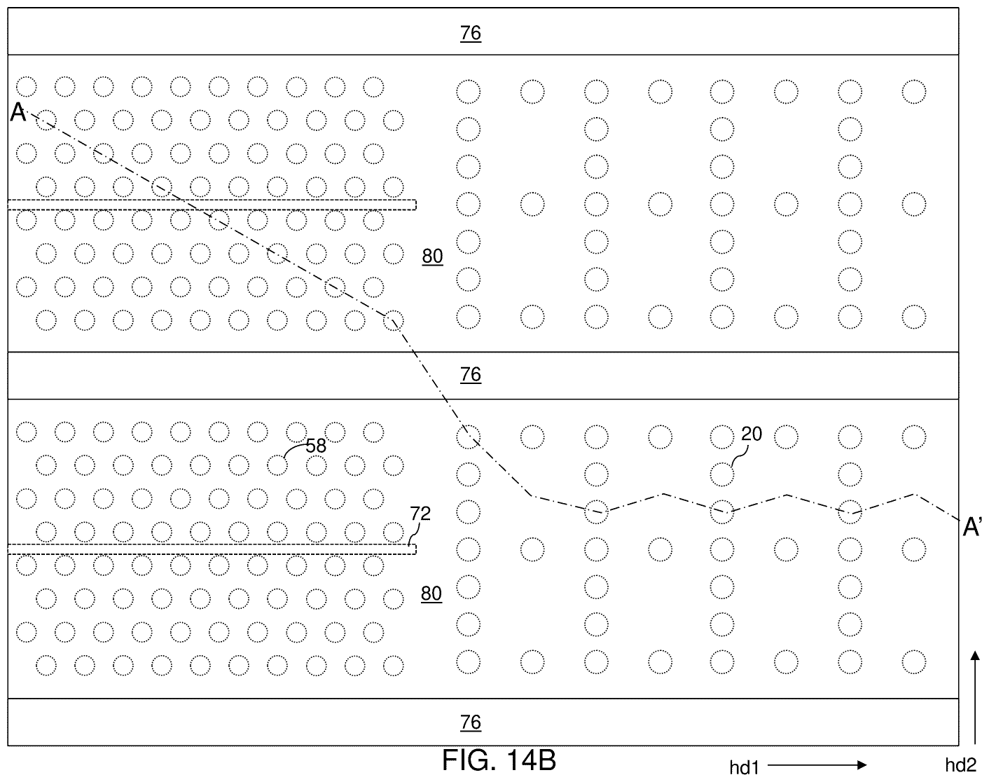

The first exemplary structure comprises a memory array region 100 in which a three-dimensional array of memory elements is to be subsequently formed, and a contact region 300 in which layer contact via structures contacting word lines are to be subsequently formed. Drain-select-level isolation structures (shown in FIGS. 14A and 14B below) laterally extending along a first horizontal direction hd1 may be formed through a subset of the uppermost sacrificial material layers 42 that will be replaced with drain side select gate electrodes.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

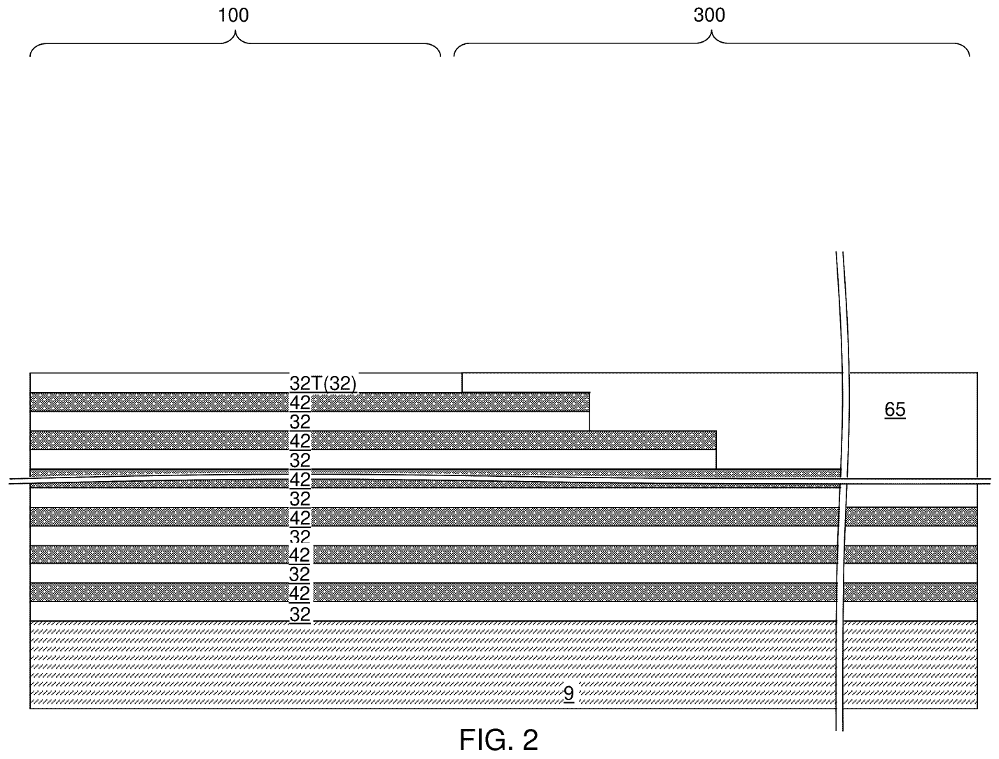

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

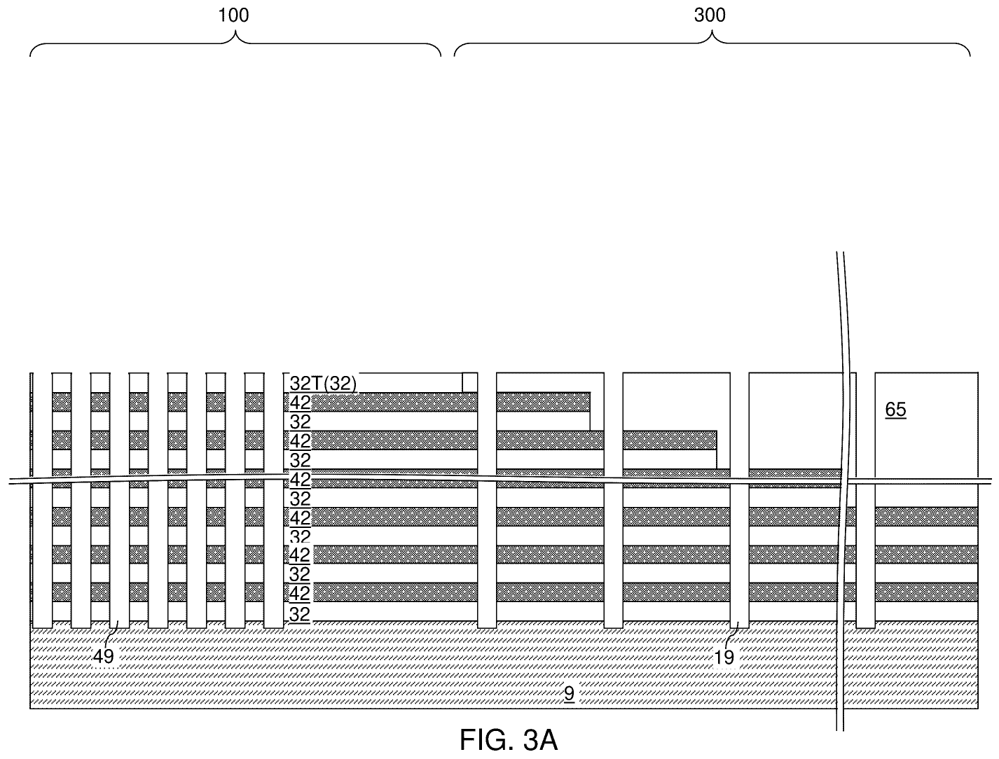

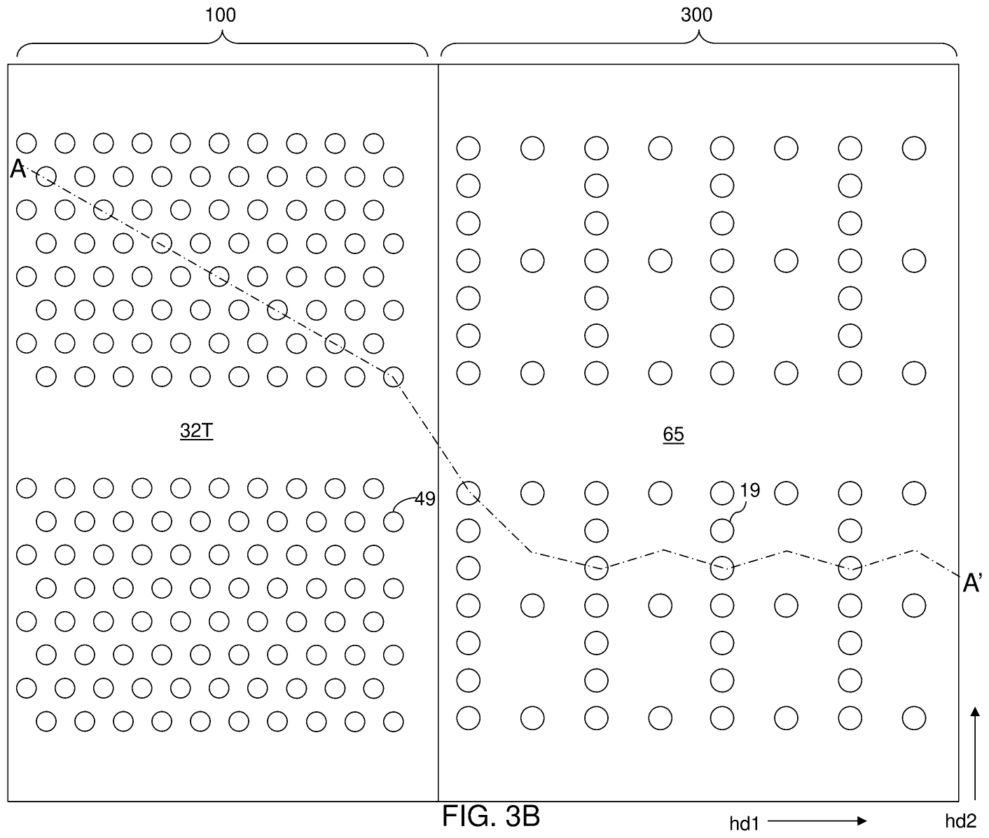

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater thicknesses may be employed. The support openings 19 may have a diameter in a range from 60 nm to 400 nm, such as from 120 nm to 300 nm, although lesser and greater thicknesses may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction (e.g., word line direction) hd1 with a uniform pitch. The rows of memory openings 49 may be laterally spaced from each other along the second horizontal direction hd2 (which may be a bit line direction), which may be perpendicular to the first horizontal direction hd1. In one embodiment, each cluster of memory openings 49 may be formed as a two-dimensional periodic array of memory openings 49.

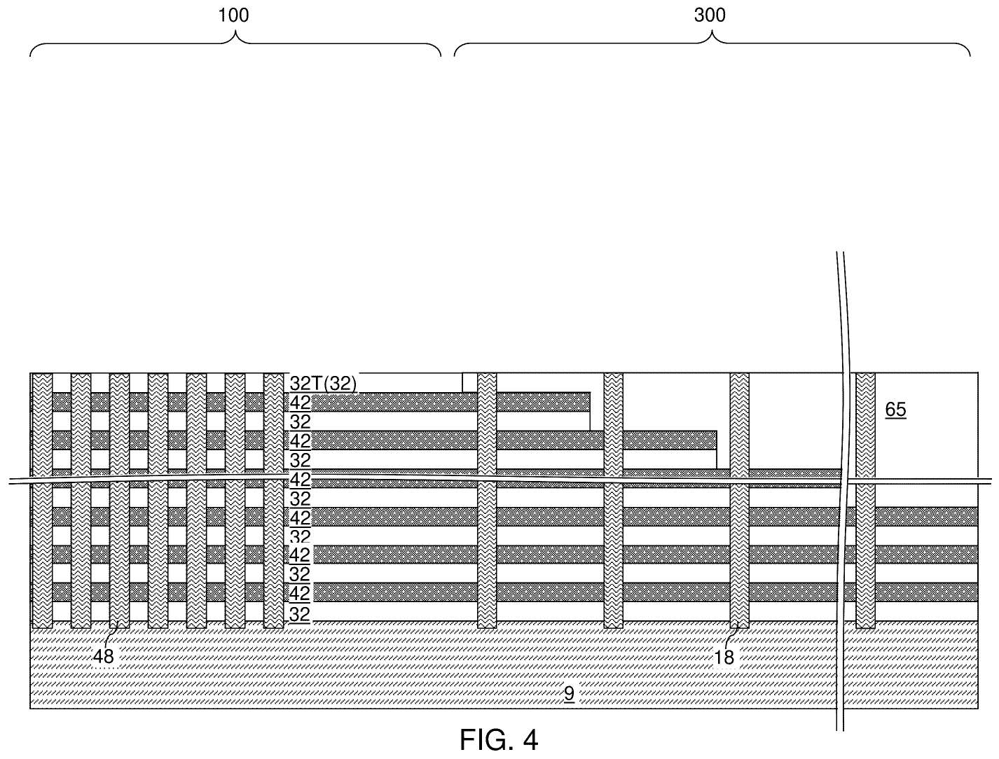

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fill a support opening 19 constitutes a sacrificial support opening fill structure 18.

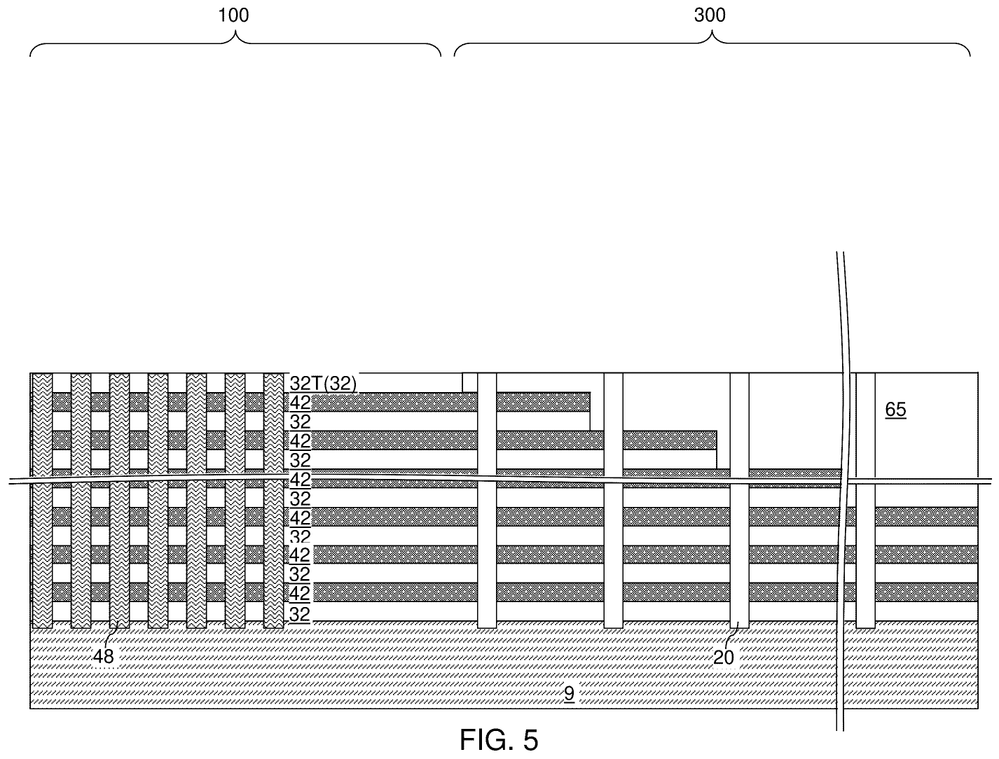

Referring to FIG. 5, a photoresist layer (not shown) can be applied over the first exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

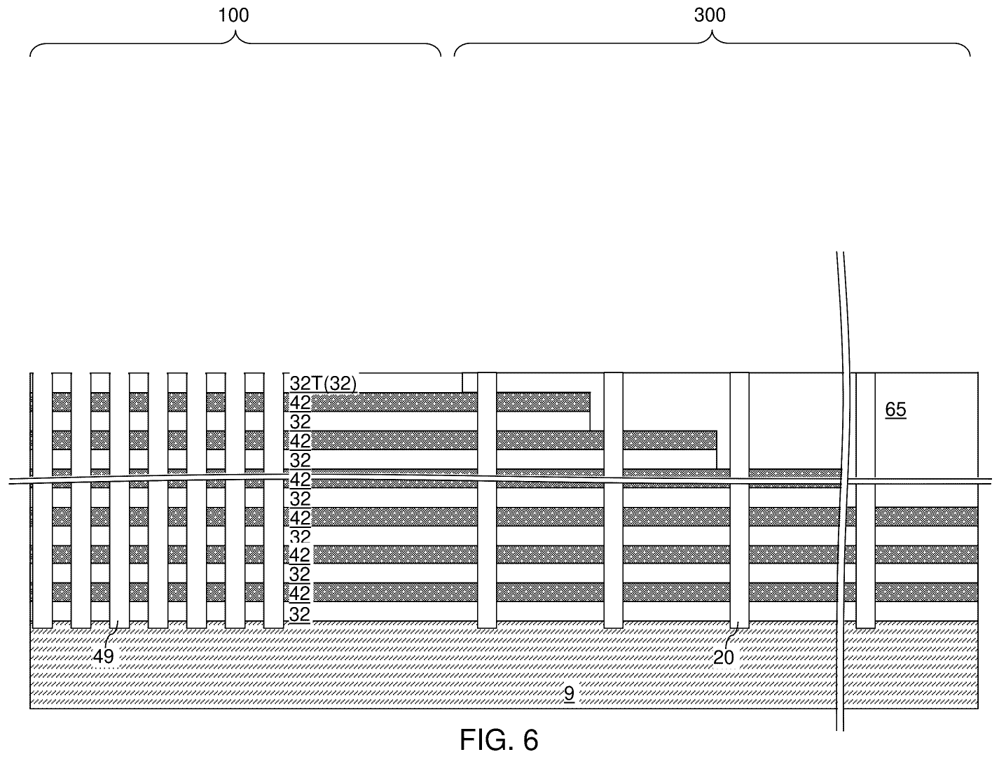

Referring to FIG. 6, sacrificial memory opening fill structures 48 are subsequently removed selective to the materials of the insulating layers 32, the sacrificial material layers 42, and the carrier substrate 9. Voids are formed in the volumes of the memory openings 49 from which the sacrificial memory opening fill structures 48 are removed.

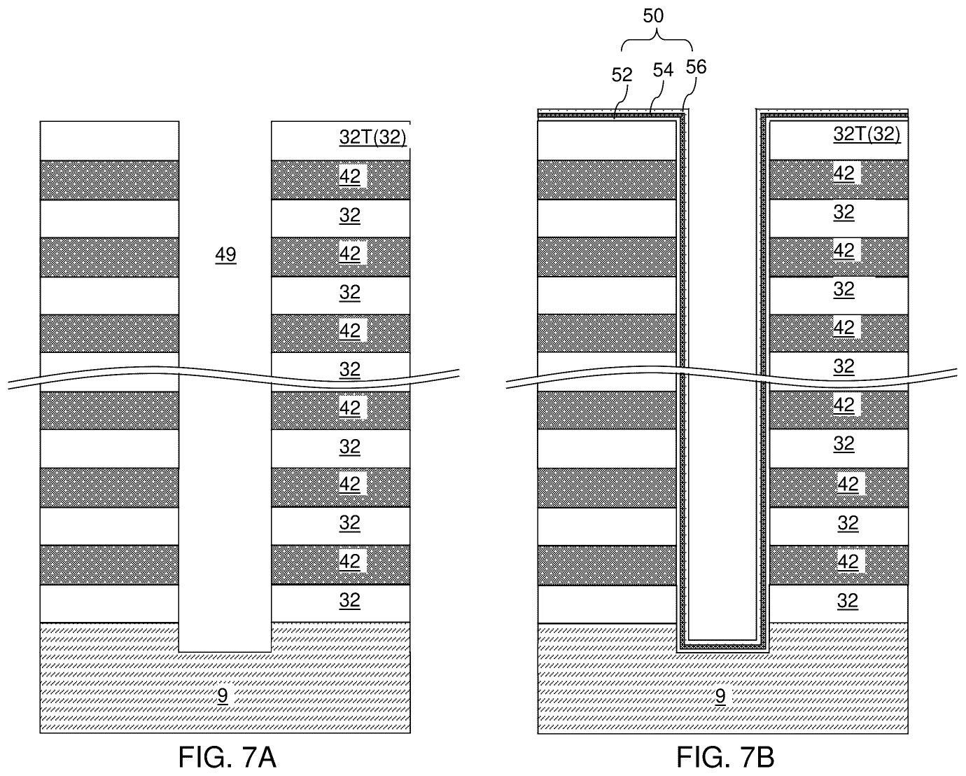

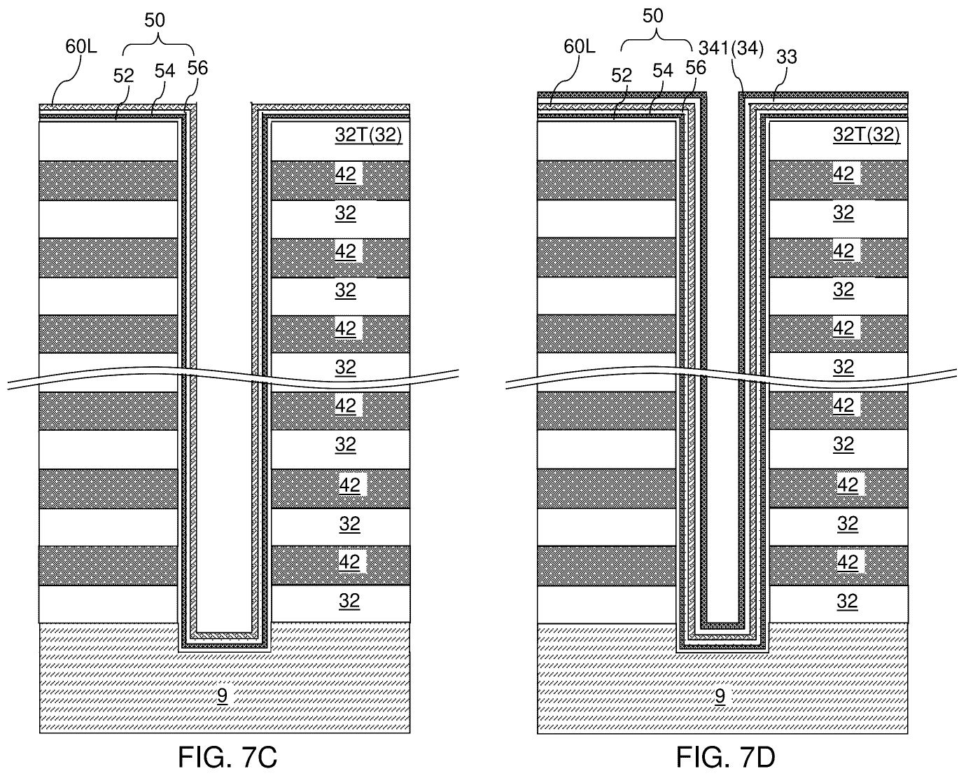

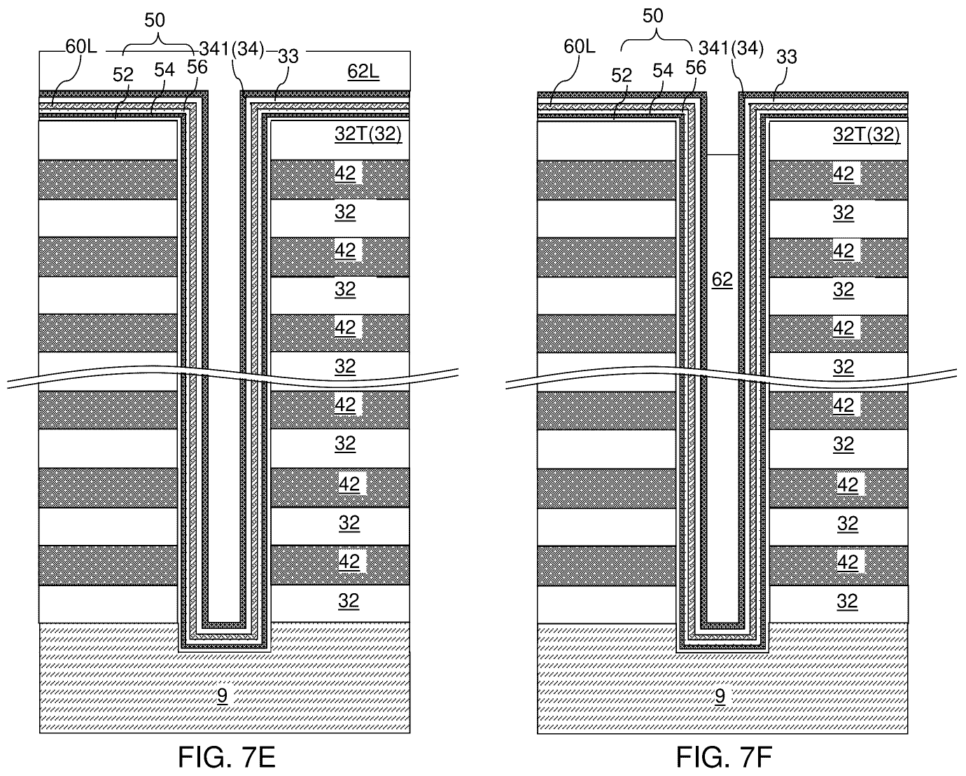

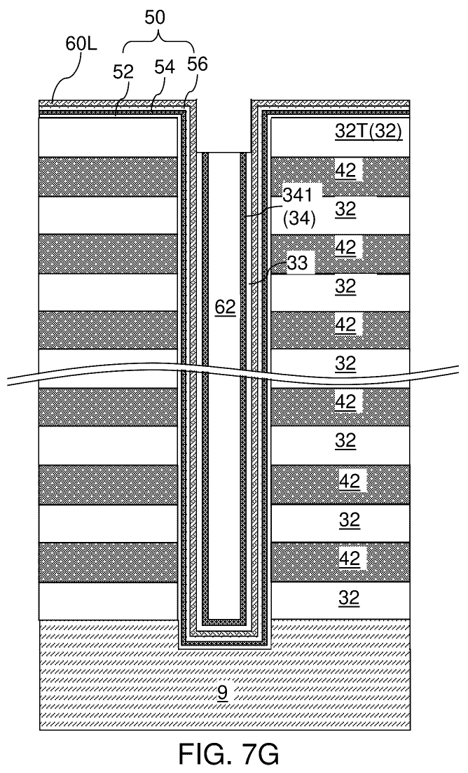

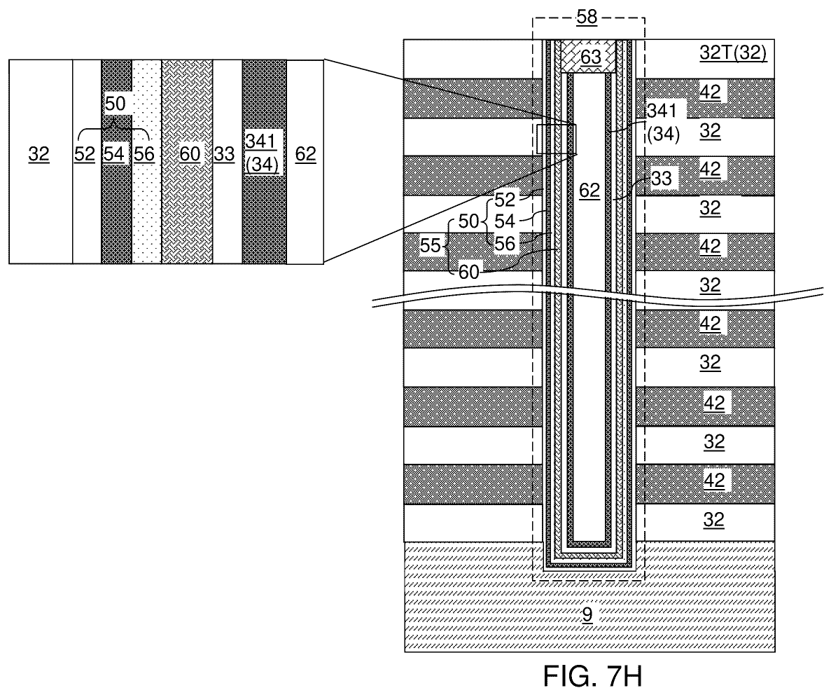

FIGS. 7A-7H are sequential vertical cross-sectional views of a memory opening 49 during formation of a memory opening fill structure 58 having a first configuration according to an embodiment of the present disclosure.

Referring to FIG. 7A, a memory opening 49 is illustrated after the processing steps of FIG. 6.

Referring to FIG. 7B, a memory film 50 is formed, which includes a layer stack containing a charge storage layer 54 and a tunneling dielectric layer 56. In an illustrative example, the layer stack may comprise an optional blocking dielectric layer 52, the charge storage layer 54, and a tunneling dielectric layer 56. The blocking dielectric layer 52, if present, can include a single dielectric material layer or a stack of a plurality of dielectric material layers. In one embodiment, the blocking dielectric layer 52 can include silicon oxide. In this case, the silicon oxide material of the blocking dielectric layer 52 can be formed by a conformal deposition method such as low pressure chemical vapor deposition, atomic layer deposition, or a combination thereof.

Alternatively or additionally, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 can include a dielectric metal oxide having a dielectric constant greater than 7.9, i.e., having a dielectric constant greater than the dielectric constant of silicon nitride. Non-limiting examples of dielectric metal oxides include aluminum oxide (Al₂O₃), hafnium oxide (HfO₂), lanthanum oxide (LaO₂), yttrium oxide (Y₂O₃), tantalum oxide (Ta₂O₅), silicates thereof, nitrogen-doped compounds thereof, alloys thereof, and stacks thereof. In one embodiment, the blocking dielectric layer 52 can include multiple dielectric metal oxide layers having different material compositions.

The thickness of the dielectric semiconductor compound can be in a range from 1nm to 20 nm, such as from 3 nm to 10 nm, although lesser and greater thicknesses can also be employed. Alternatively, the blocking dielectric layer 52 can be omitted, and an outer blocking dielectric layer can be formed after formation of backside recesses on surfaces of memory films to be subsequently formed.

The charge storage layer 54 may be formed on the blocking dielectric layer 52, or may be formed on sidewalls of the alternating stack (32, 42) in case the blocking dielectric layer is omitted. In one embodiment, the charge storage layer 54 can be a continuous layer or patterned discrete portions of a charge trapping material including a dielectric charge trapping material, which can be, for example, silicon nitride. Alternatively, the charge storage layer 54 can include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the charge storage layer 54 includes a silicon nitride layer. In one embodiment, the sacrificial material layers 42 and the insulating layers 32 can have vertically coincident sidewalls, and the charge storage layer 54 can be formed as a single continuous layer.

In another embodiment, the sacrificial material layers 42 can be laterally recessed with respect to the sidewalls of the insulating layers 32 prior to formation of the blocking dielectric layer 52, and a combination of a deposition process and an anisotropic etch process can be employed to form the charge storage layer 54 as a plurality of memory material portions that are vertically spaced apart. While an embodiment is illustrated in which the charge storage layer 54 is a single continuous layer, embodiments are expressly contemplated herein in which the charge storage layer 54 is replaced with a plurality of memory material portions (which can be charge trapping material portions or electrically isolated floating gates) that are vertically spaced apart.

In one embodiment, each vertical stack of memory elements comprises a vertical stack of charge storage material portions (i.e., portions of the charge storage layer 54 or a plurally of vertically spaced apart charge trapping material portions or floating gates) that retain electrical charges therein upon programming, or a vertical stack of ferroelectric memory elements that retains electrical polarization therein upon programming. The charge storage layer 54 can be formed as a single charge storage layer of homogeneous composition, or can include a stack of multiple charge storage layers. The multiple charge storage layers, if employed, can comprise a plurality of spaced-apart floating gate material layers that contain conductive materials (e.g., metal such as tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof) and/or semiconductor materials (e.g., polycrystalline or amorphous semiconductor material including at least one elemental semiconductor element or at least one compound semiconductor material). Alternatively or additionally, the charge storage layer 54 may comprise an insulating charge trapping material, such as one or more silicon nitride segments. Alternatively, the charge storage layer 54 may comprise conductive nanoparticles such as metal nanoparticles, which can be, for example, ruthenium nanoparticles. The charge storage layer 54 can be formed, for example, by chemical vapor deposition (CVD), atomic layer deposition (ALD), physical vapor deposition (PVD), or any suitable deposition technique for storing electrical charges therein. The thickness of the charge storage layer 54 can be in a range from 2 nm to 20 nm, although lesser and greater thicknesses can also be employed.

The tunneling dielectric layer 56 includes a tunneling dielectric material, which is a dielectric material through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The tunneling dielectric layer 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the tunneling dielectric layer 56 can include a stack of a first silicon oxide layer, a silicon oxynitride layer, and a second silicon oxide layer, which is commonly known as an ONO stack. In one embodiment, the tunneling dielectric layer 56 can include a silicon oxide layer that is substantially free of carbon or a silicon oxynitride layer that is substantially free of carbon. The thickness of the tunneling dielectric layer 56 can be in a range from 2 nm to 20 nm, although lesser and greater thicknesses can also be employed.

Referring to FIG. 7C, a semiconductor channel material layer 60L can be deposited over each memory film 50 by performing a conformal deposition process. The semiconductor channel material layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L includes amorphous silicon or polysilicon. The semiconductor channel material layer 60L can have a doping of a first conductivity type, which may be p-type or n-type. The semiconductor channel material layer 60L can be formed by a conformal deposition method such as low pressure chemical vapor deposition (LPCVD). The thickness of the semiconductor channel material layer 60L may be in a range from 5 nm to 50 nm, such as from 10 nm to 30 nm, although lesser and greater thicknesses may also be employed. A cavity is present in a center portion of the memory opening 49 after formation of the semiconductor channel material layer 60L. The tunneling dielectric layer 56 is in contact with an outer sidewall of the semiconductor channel material layer 60L.

Referring to FIG. 7D, a dielectric liner 33 and a core-side charge trapping material layer 34 can be sequentially formed by performing conformal deposition processes. In the embodiment of FIG. 7D, the dielectric liner 33 comprises, and/or consists essentially of, silicon oxide. In one embodiment, the dielectric liner 33 is a silicon oxide liner. The dielectric liner 33 may be formed by a low pressure chemical vapor deposition process or an atomic layer deposition process. The thickness of the dielectric liner 33 may be in a range from 2 nm to 20 nm, such as from 4 nm to 12 nm, although lesser and greater thicknesses may also be employed.

The core-side charge trapping material layer 34 comprises a dielectric charge trapping material that traps electrons therein. In one embodiment, the core-side charge trapping material layer 34 may be formed as a charge trapping dielectric material layer 341 having a homogeneous material composition throughout.

In one embodiment, the core-side charge trapping material layer 34 comprises and/or consist essentially of silicon nitride. In another embodiment, the core-side charge trapping material layer 34 comprises and/or consists essentially of a dielectric metal oxide material, such as aluminum oxide. In another embodiment, the core-side charge trapping material layer 34 comprises and/or consists essentially of a silicon oxynitride. The core-side charge trapping material layer 34 can be formed by a conformal deposition process, such as a chemical vapor deposition process or an atomic layer deposition process. The thickness of the core-side charge trapping material layer 34 may be in a range from 1 nm to 20 nm, such as from 2 nm to 10 nm, although lesser and greater thicknesses may also be employed.

Referring to FIG. 7E, a dielectric core layer 62L comprising a dielectric fill material, such as silicon oxide, can be deposited in remaining volumes of the memory openings 49. In one embodiment, the dielectric core layer 62L comprises an as-deposited silicon oxide layer deposited using a conformal deposition process, such as a chemical vapor deposition process. As used herein, an as-deposited silicon oxide layer comprises silicon oxide upon deposition, rather than being formed as a silicon layer followed by oxidation of the silicon to form silicon oxide, for example. In one embodiment, the dielectric core layer 62L is in direct contact with an inner sidewall of the core-side charge trapping material layer 34.

Referring to FIG. 7F, the dielectric core layer 62L can be vertically recessed such that each remaining portion of the dielectric core layer 62L has a top surface at or about the horizontal plane including the bottom surface of the topmost insulating layer 32T. Each remaining portion of the dielectric core layer 62L constitutes a dielectric core 62.

Referring to FIG. 7G, at least one isotropic etch process can be performed to etch physically exposed portions of the core-side charge trapping material layer 34 and the dielectric liner 33. For example, a first isotropic etch process, such as a first wet etch process, can be performed to remove physically exposed portions of the core-side charge trapping material layer 34. A second isotropic etch process, such as a second wet etch process, can be performed to remove physically exposed portions of the dielectric liner 33. Surface segments of the semiconductor channel material layer 60L can be physically exposed after performing the at least one isotropic etch process.

Referring to FIG. 7H, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical polishing (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

In one embodiment, a memory film 50 may comprise an optional blocking dielectric layer 52, a charge storage layer 54, and an optional tunneling dielectric layer 56. Each contiguous combination of a memory film 50 and a vertical semiconductor channel 60 constitutes a memory stack structure 55. Each combination a memory stack structure 55, a dielectric core 62, the core-side charge trapping material layer 34, the dielectric liner 33 and a drain region 63 within a memory opening 49 constitutes a memory opening fill structure 58. The drain region 63 contacts an annular top surface of the core-side charge trapping material layer 34 and an end portion of the vertical semiconductor channel 60. Each memory opening fill structure 58 comprises a respective vertical stack of memory elements, which may comprise portions of the charge storage layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material.

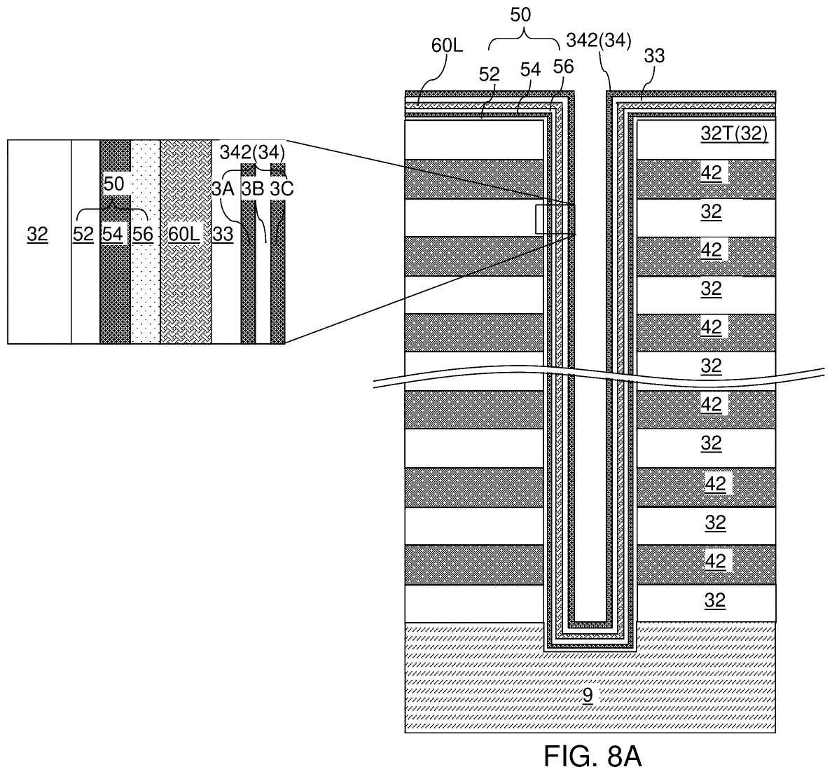

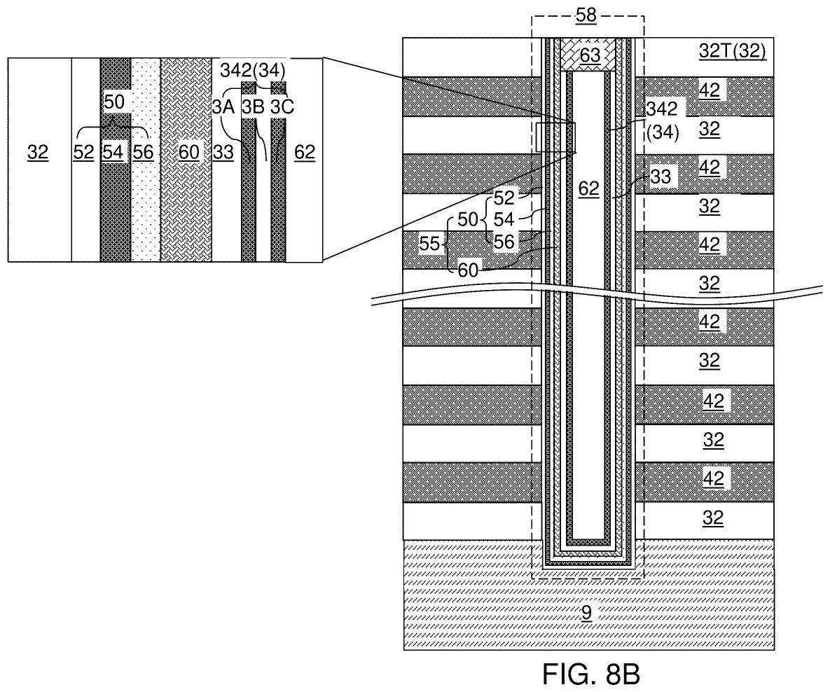

FIGS. 8A and 8B are sequential vertical cross-sectional views of a memory opening 49 during formation of a memory opening fill structure 58 having a second configuration according to an embodiment of the present disclosure.

Referring to FIG. 8A, the configuration of the first exemplary structure illustrated in FIG. 8A can be derived from the first exemplary structure described with reference to FIG. 7C by forming a dielectric liner 33 and by forming a core-side charge trapping material layer 34 which is a composite charge trapping dielectric 342 including a layer stack of a plurality of component material layers (3A, 3B, 3C). The dielectric liner 33 illustrated in FIG. 8A may be the same as the dielectric liner 33 described with reference to FIG. 7D.

The composite charge trapping dielectric 342 comprises a layer stack including a first silicon nitride layer 3A, a silicon oxynitride layer 3B, and a second silicon nitride layer 3C. The composite charge trapping dielectric 342 provides enhanced stability for electrons trapped therein.

Referring to FIG. 8B, the processing steps described with reference to FIGS. 7E-7H can be performed to provide a memory opening fill structure 58 having a second configuration.

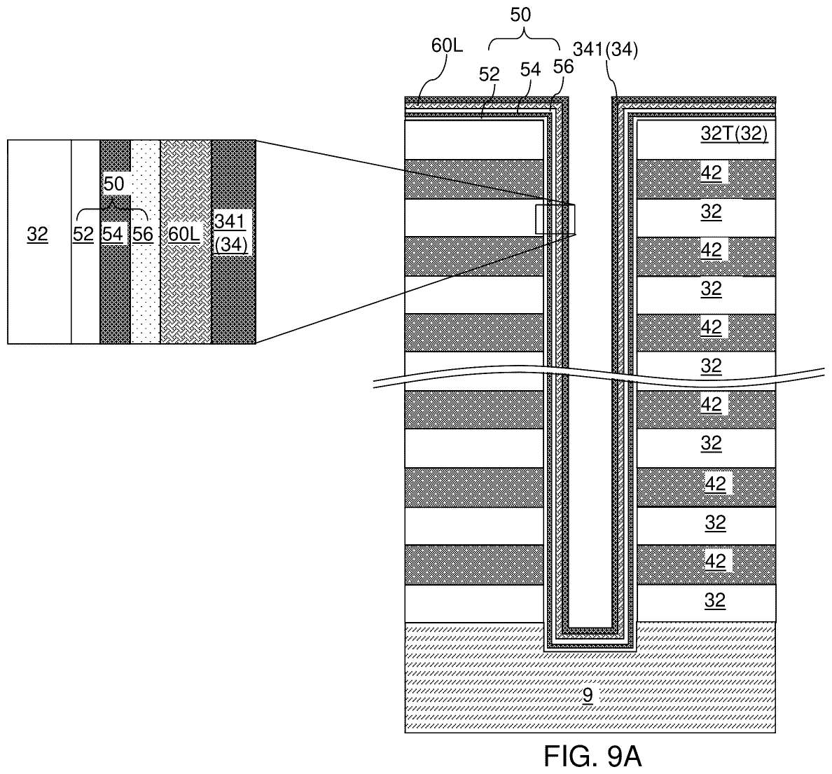

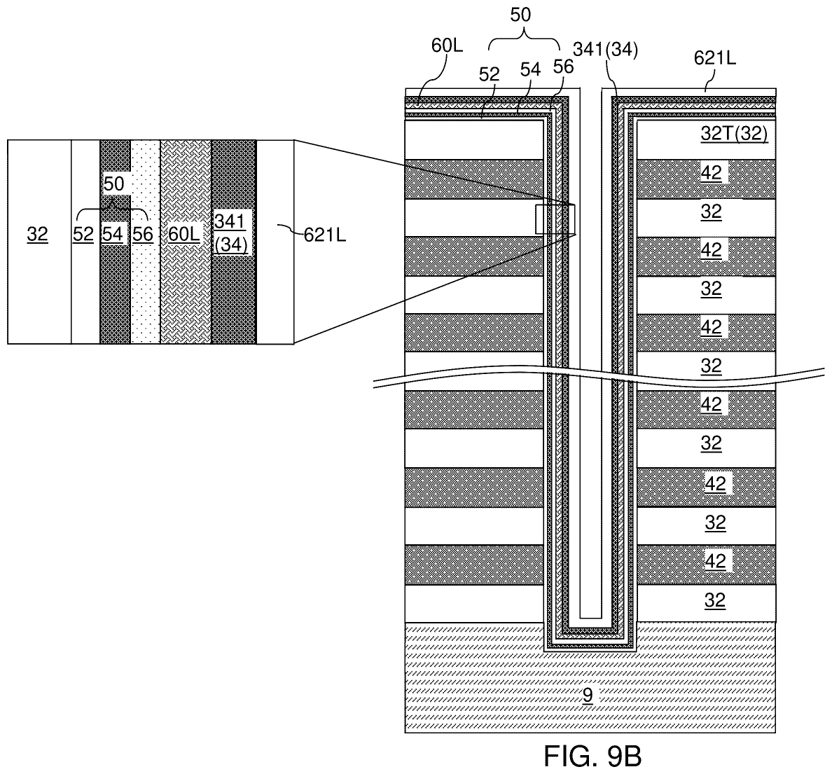

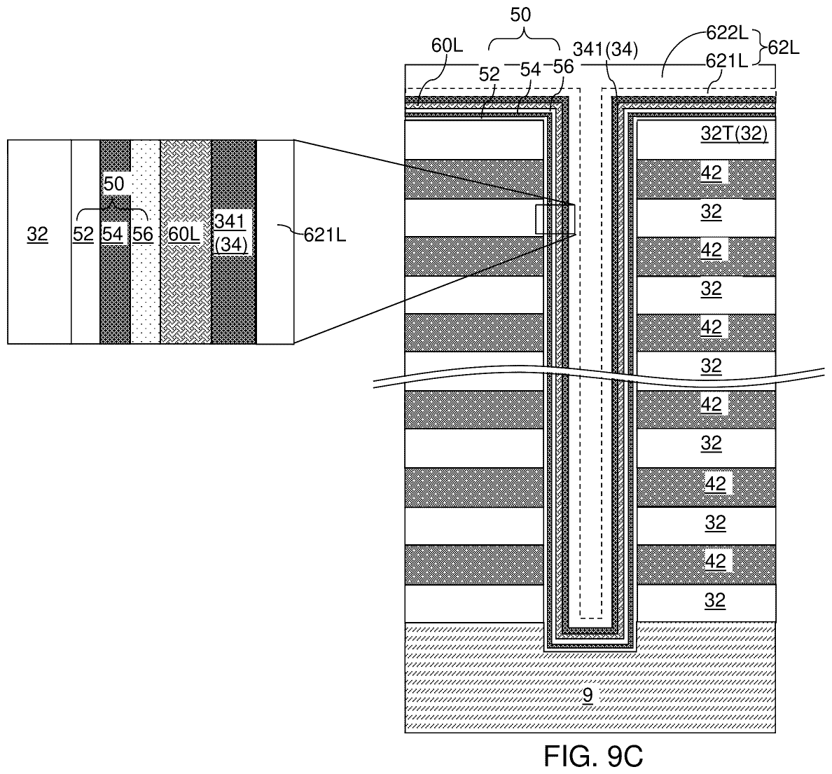

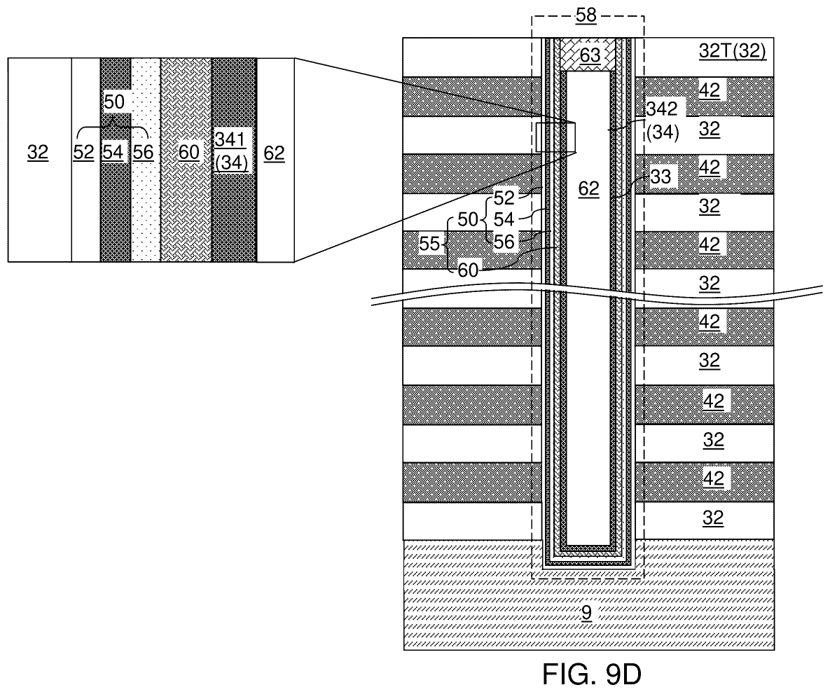

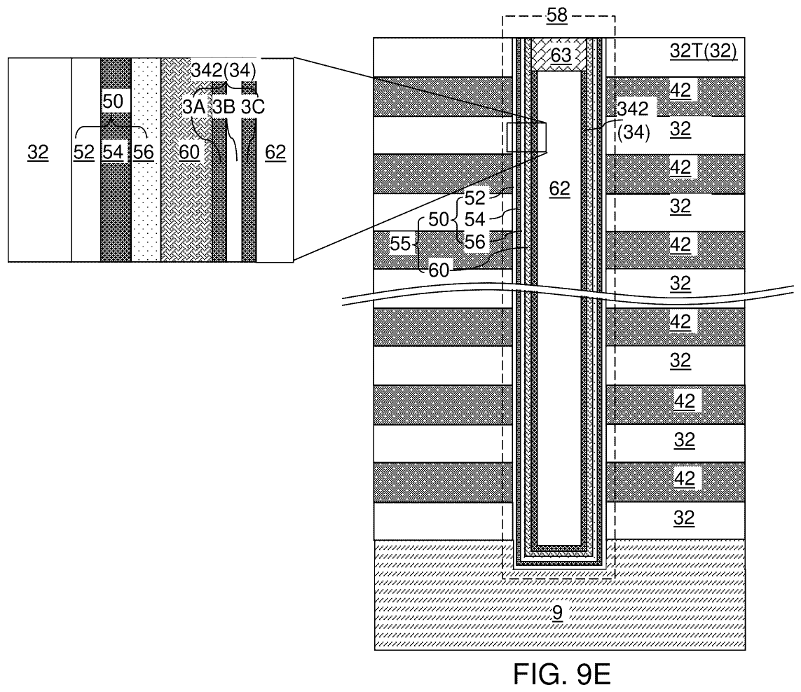

FIGS. 9A-9D are sequential vertical cross-sectional views of a memory opening 49 during formation of a memory opening fill structure 58 having a third configuration according to an embodiment of the present disclosure.

Referring to FIG. 9A, the configuration of the first exemplary structure illustrated in FIG. 9A can be derived from the first exemplary structure described with reference to FIG. 7D by omitting formation of a dielectric liner 33 and by forming a core-side charge trapping material layer 34 directly on the inner sidewall of the semiconductor channel material layer 60L. The core-side charge trapping material layer 34 may comprise the above described charge trapping dielectric material layer 341, and may have any material composition that may be employed for the charge trapping dielectric material layer 341 in the first configuration of the memory opening fill structure 58 described with reference to FIGS. 7A-7H.

Referring to FIG. 9B, a first silicon oxide material layer 621L can be conformally deposited over the core-side charge trapping material layer 34. The thickness of the first silicon oxide material layer 621L can be selected such that a void that is not filled within the first silicon oxide material layer 621L vertically extends through the memory opening 49. An anneal at an elevated temperature may be performed in a hydrogen-containing environment to increase the density of charge traps in the core-side charge trapping material layer 34. The elevated temperature may be 600 to 800 degrees Celsius, and the duration of the anneal process may be in a range from 10 minutes to 120 minutes, although shorter and longer durations may also be employed.

Referring to FIG. 9C, a second silicon oxide material layer 622L can be conformally deposited over the first silicon oxide material layer 621L to fill the void within the memory opening 49. The combination of the first silicon oxide material layer 621L and the second silicon oxide material layer 622L constitutes a dielectric core layer 62L, which may occupy the same volume as the dielectric core layer 62L described with reference to FIG. 7E. The dielectric core layer 62L may comprises a silicon oxide layer.

Referring to FIG. 9D, the processing steps described with reference to FIGS. 7F, 7G, and 7H can be performed to form a dielectric core 62 and a drain region 63. The at least one isotropic etch process described with reference to FIG. 7G can be modified in view of absence of the dielectric liner 33.

FIG. 9E is a vertical cross-sectional view of a memory opening fill structure 58 having a fourth configuration according to an embodiment of the present disclosure. The fourth configuration of the memory opening fill structure 58 can be derived from the third configuration of the memory opening fill structure 58 of FIG. 9D by employing the composite charge trapping dielectric 342 of FIG. 8A as the core-side charge trapping material layer 34 in lieu of the charge trapping dielectric material layer 341 described with reference to FIG. 7D.

Referring collectively to FIGS. 7H, 8B, 9D, and 9E, the core-side charge trapping material layer 34 may be laterally spaced from the vertical semiconductor channel 60 by a dielectric liner 33, or may be in contact with an inner sidewall of the vertical semiconductor channel 60. The core-side charge trapping material layer 34 may comprise a charge trapping dielectric material layer 341 having a homogenous material composition, or may comprise a composite charge trapping dielectric 342 including a layer stack of a plurality of component material layers (3A, 3B, 3C). In one embodiment, the memory film 50 comprises a layer stack that includes a tunneling dielectric layer 56 in contact with an outer sidewall of the vertical semiconductor channel 60, a charge storage layer 54 in contact with an outer sidewall of the tunneling dielectric layer 56, and an optional blocking dielectric layer 52 in contact with an outer sidewall of the charge storage layer 54.

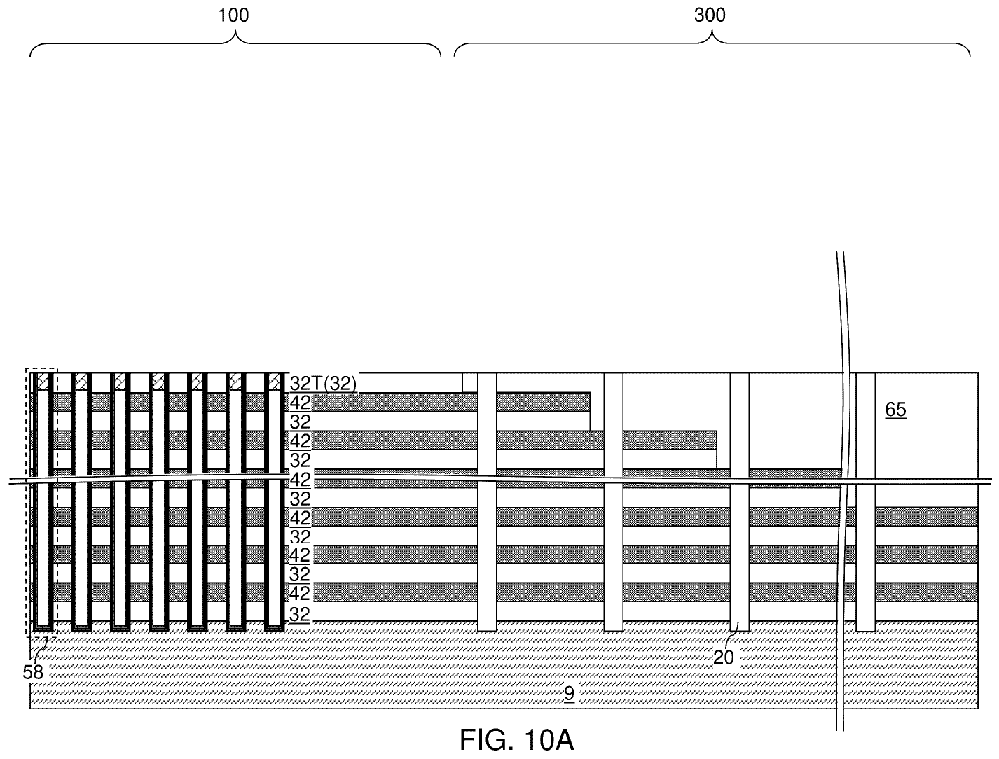

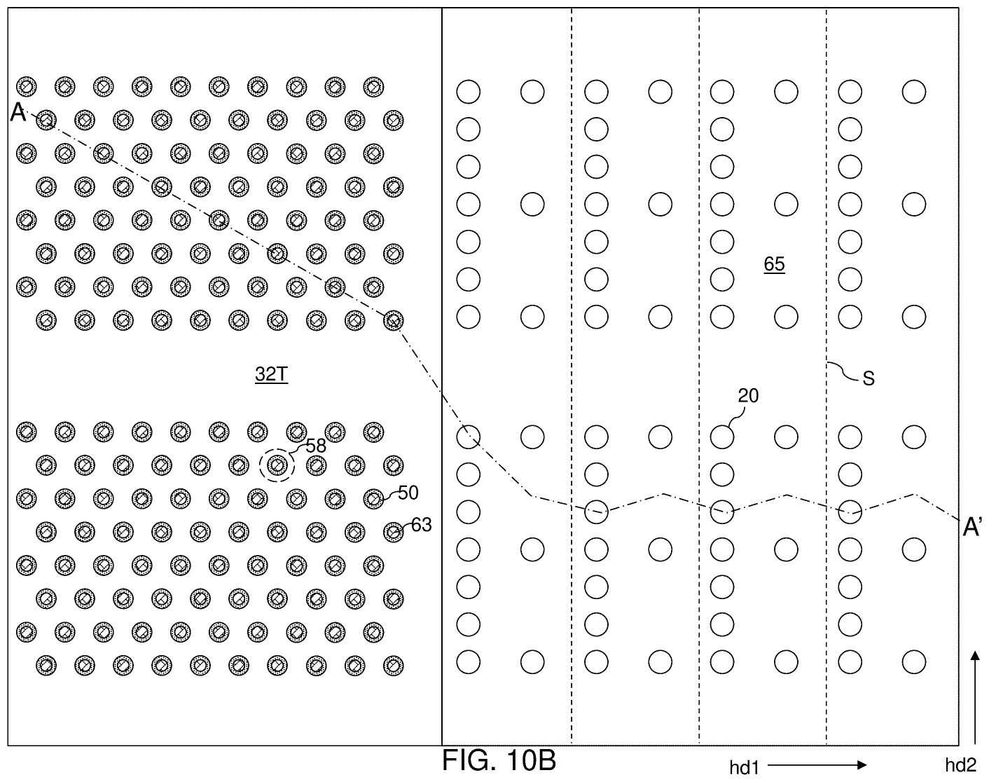

Referring to FIGS. 10A and 10B, the first exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

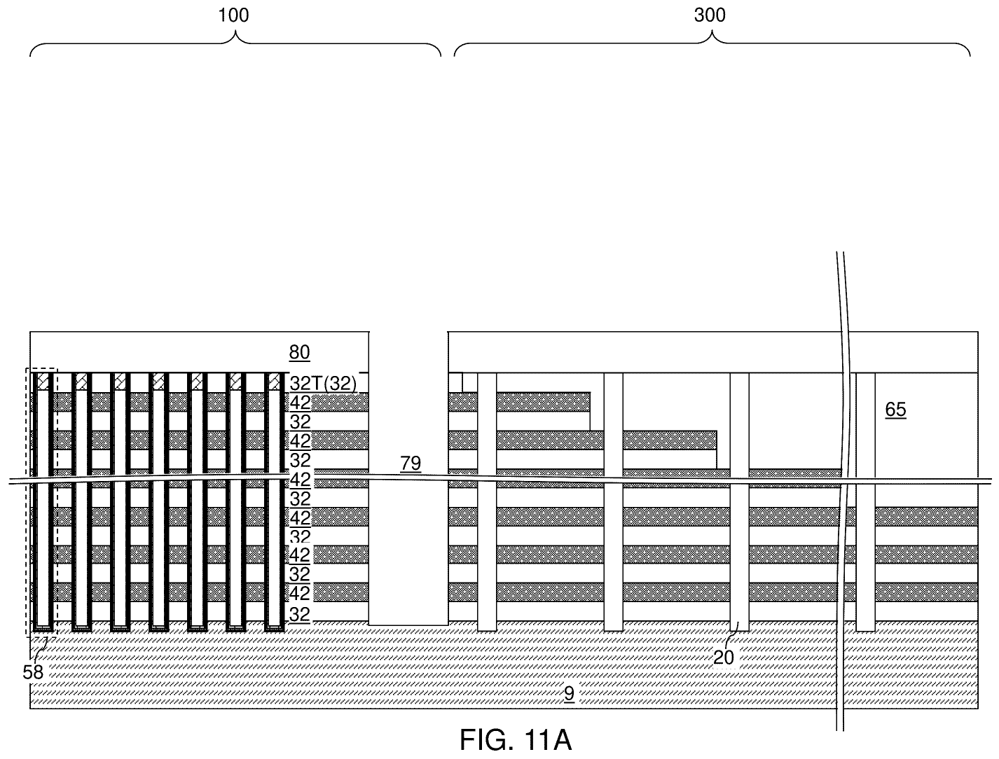

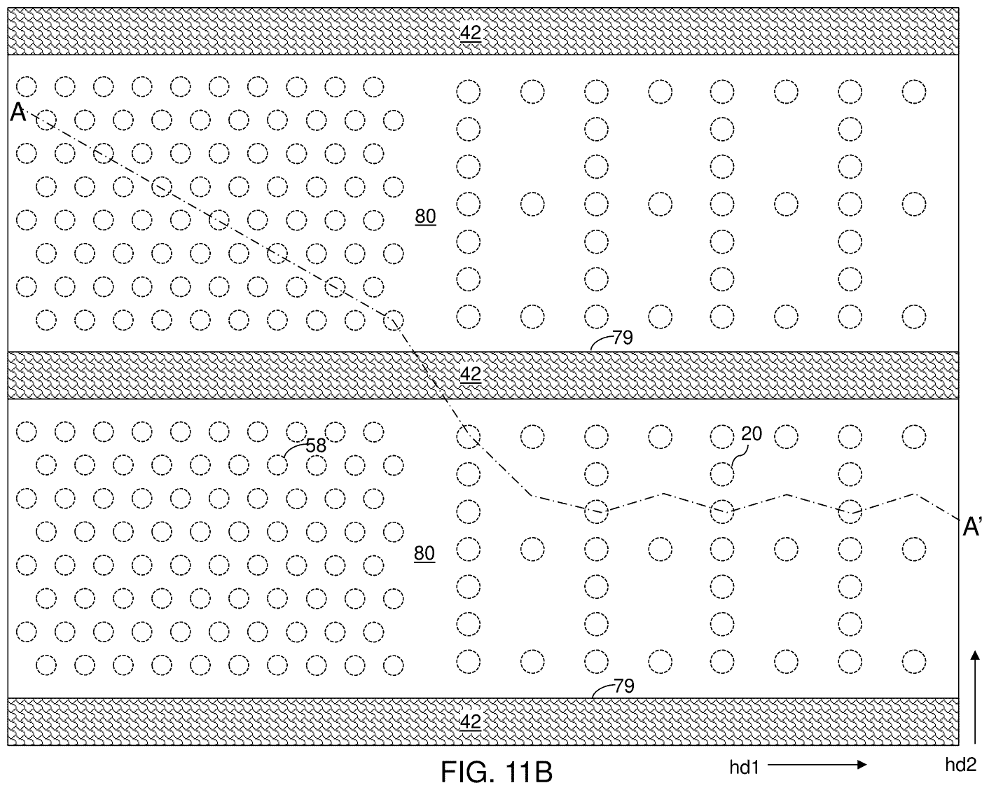

Referring to FIGS. 11A and 11B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80.

Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

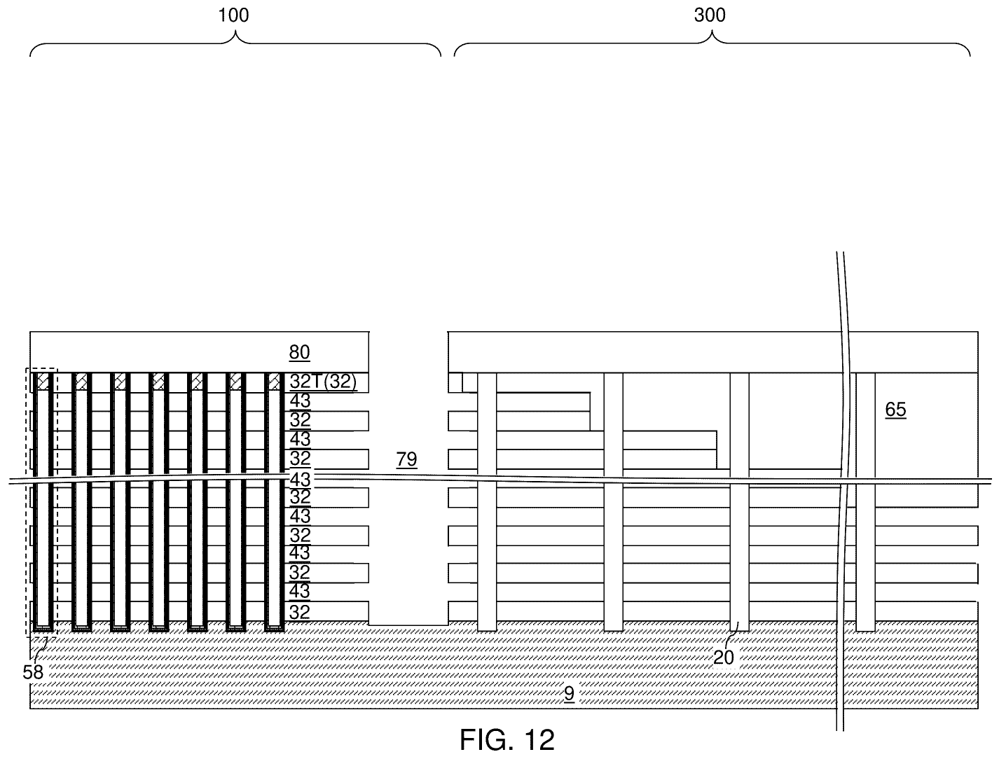

Referring to FIG. 12, an etchant that selectively etches the material of the sacrificial material layers 42 with respect to the material of the insulating layers 32 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

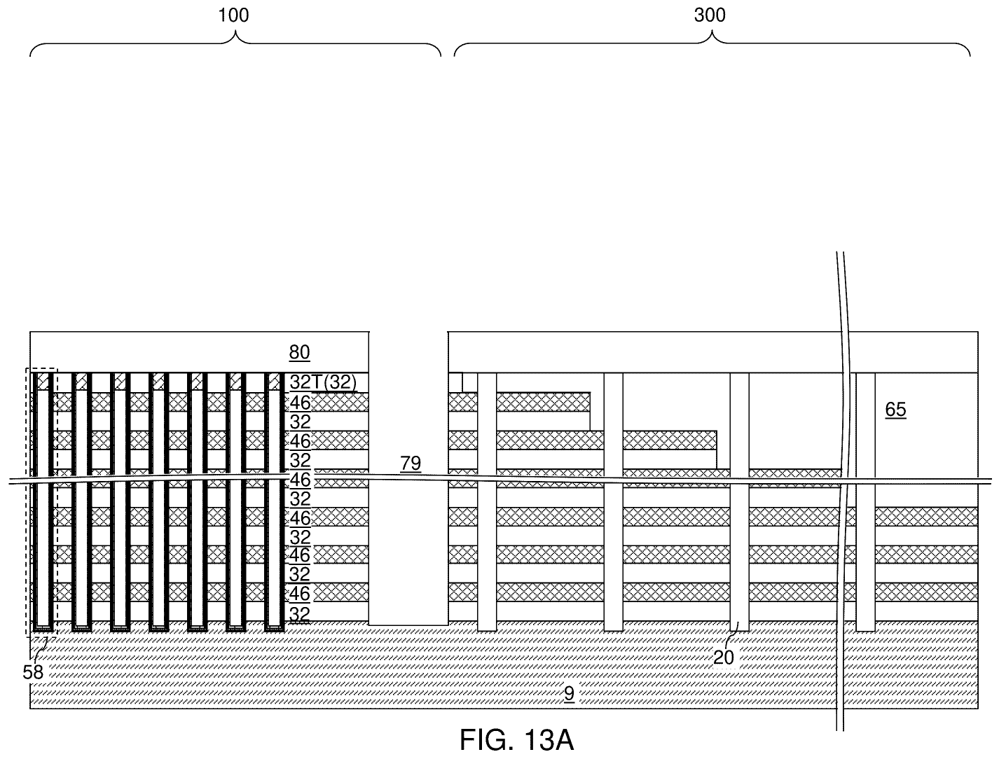

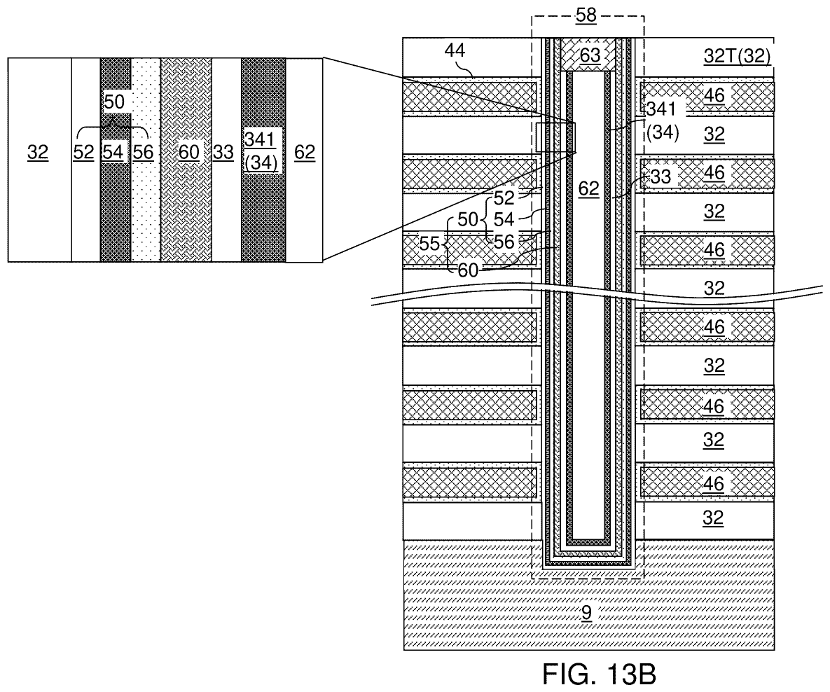

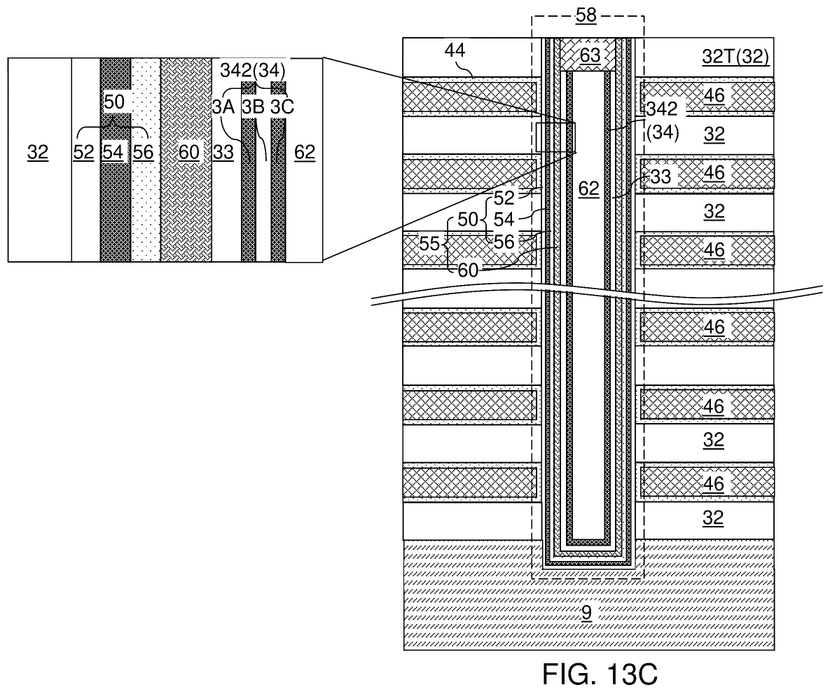

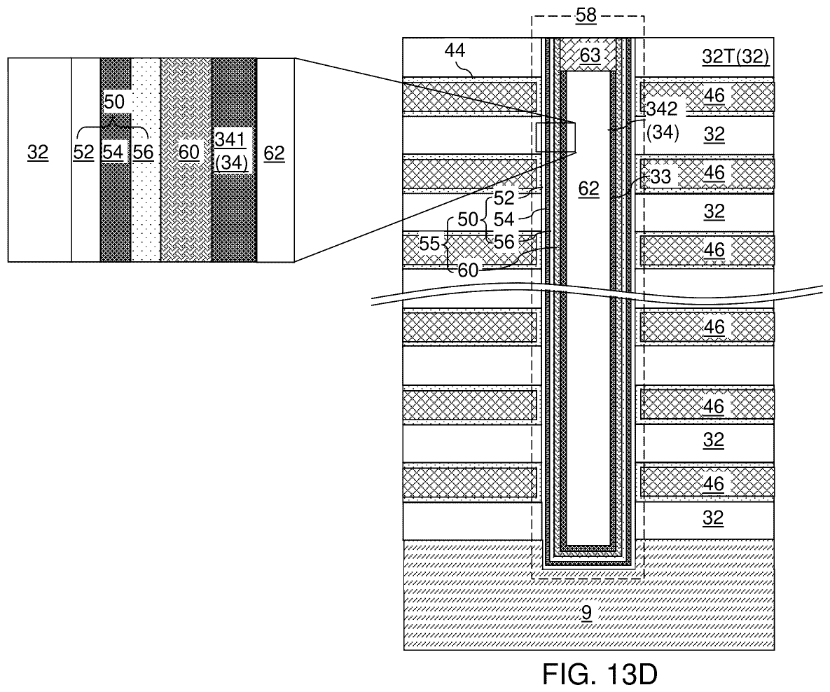

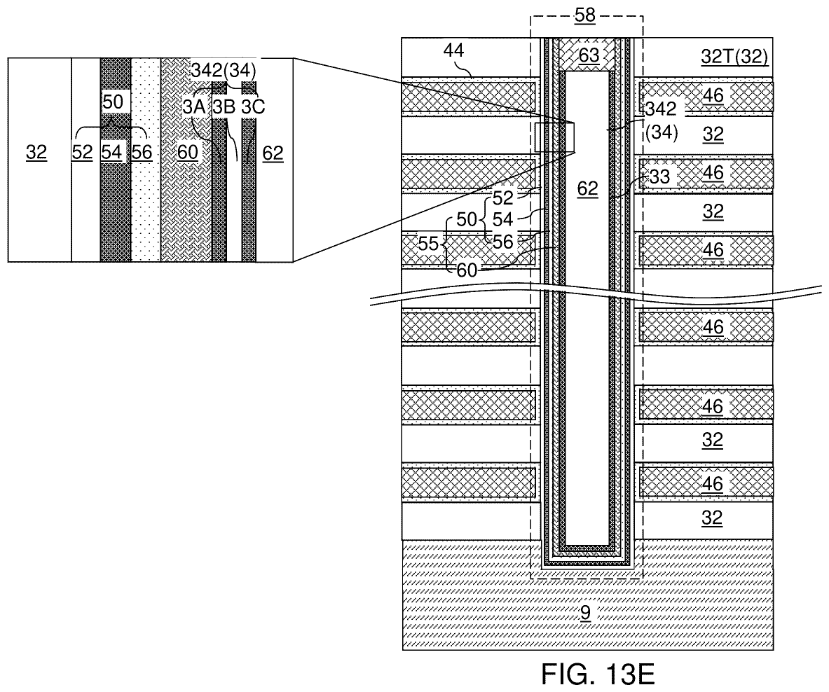

Referring to FIGS. 13A-13E, the first exemplary structure is illustrated after formation of an outer blocking dielectric layer 44 and electrically conductive layers 46. FIG. 13A is a schematic vertical cross-sectional view of the first exemplary structure after formation of electrically conductive layers according to an embodiment of the present disclosure. FIG. 13B is a magnified vertical cross-sectional view of the first exemplary structure of FIG. 13A around a memory opening fill structure 58 in case the memory opening fill structure 58 has the first configuration of FIG. 7H. FIG. 13C is a magnified vertical cross-sectional view of the first exemplary structure of FIG. 13A around a memory opening fill structure 58 in case the memory opening fill structure 58 has the second configuration of FIG. 8B. FIG. 13D is a magnified vertical cross-sectional view of the first exemplary structure of FIG. 13A around a memory opening fill structure 58 in case the memory opening fill structure 58 has the third configuration of FIG. 9D. FIG. 13E is a magnified vertical cross-sectional view of the first exemplary structure of FIG. 13A around a memory opening fill structure 58 in case the memory opening fill structure 58 has the fourth configuration of FIG. 9E.

The outer blocking dielectric layer 44, if present, comprises a dielectric material that functions as a control gate dielectric for the control gates to be subsequently formed in the lateral recesses 43. In case the blocking dielectric layer 52 is present within each memory opening, the outer blocking dielectric layer 44 is optional. In case the blocking dielectric layer 52 is omitted, the outer blocking dielectric layer 44 is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

In one embodiment, each of the electrically conductive layers 46 is laterally spaced from the blocking dielectric layer 52 by a respective outer blocking dielectric layer 44 having a respective tubular portion, a respective upper horizontally-extending portion that is adjoined to an upper end of the respective tubular portion, and a respective lower horizontally-extending portion that is adjoined to a lower end of the respective tubular portion. At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

Referring to FIGS. 14A and 14B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within each respective one of the insulating spacers. In this case, each lateral isolation trench fill structure 76 may comprise a combination of a through-stack conductive via structure and an insulating spacer that laterally surrounds the through-stack conductive via structure.

The drain-select-level isolation structures 72 are also shown. The subset of the electrically conductive layers 46 that the drain-select-level isolation structures 72 cut through comprise drain side select gate electrodes for the NAND strings comprising the memory opening fill structures 58.

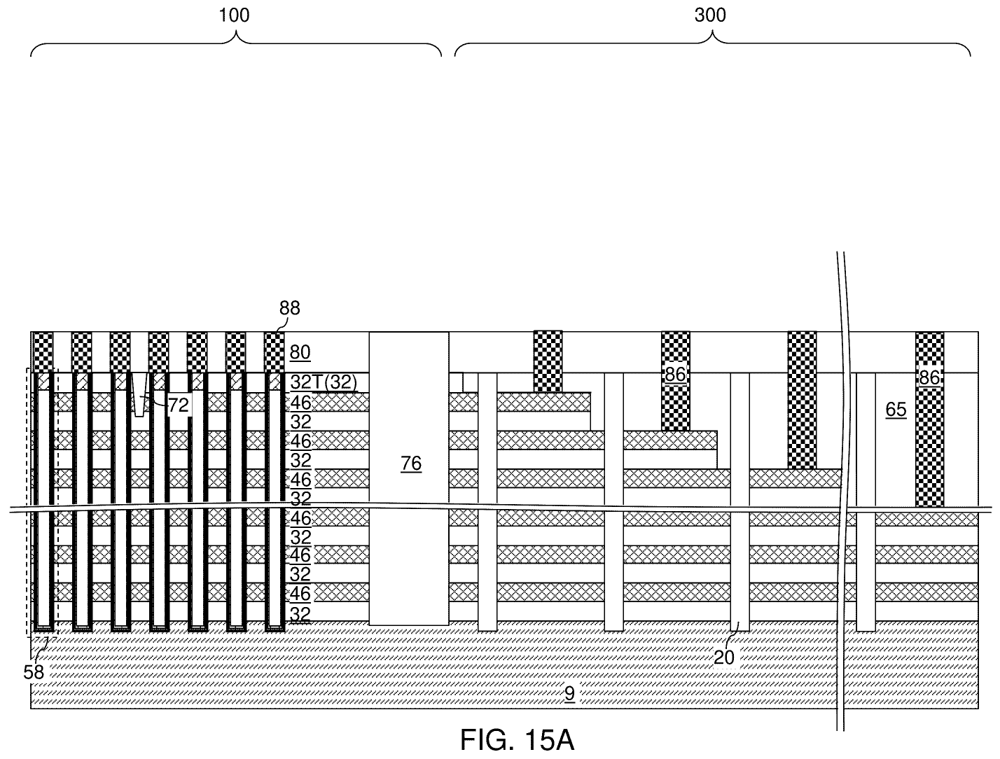

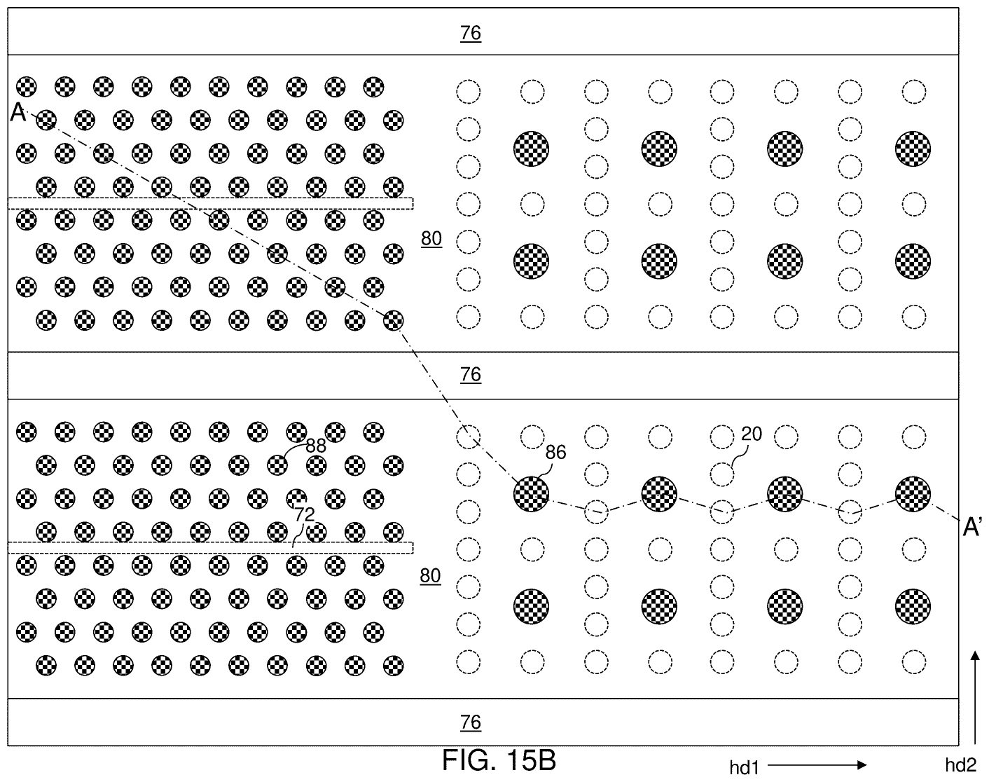

Referring to FIGS. 15A and 15B, contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

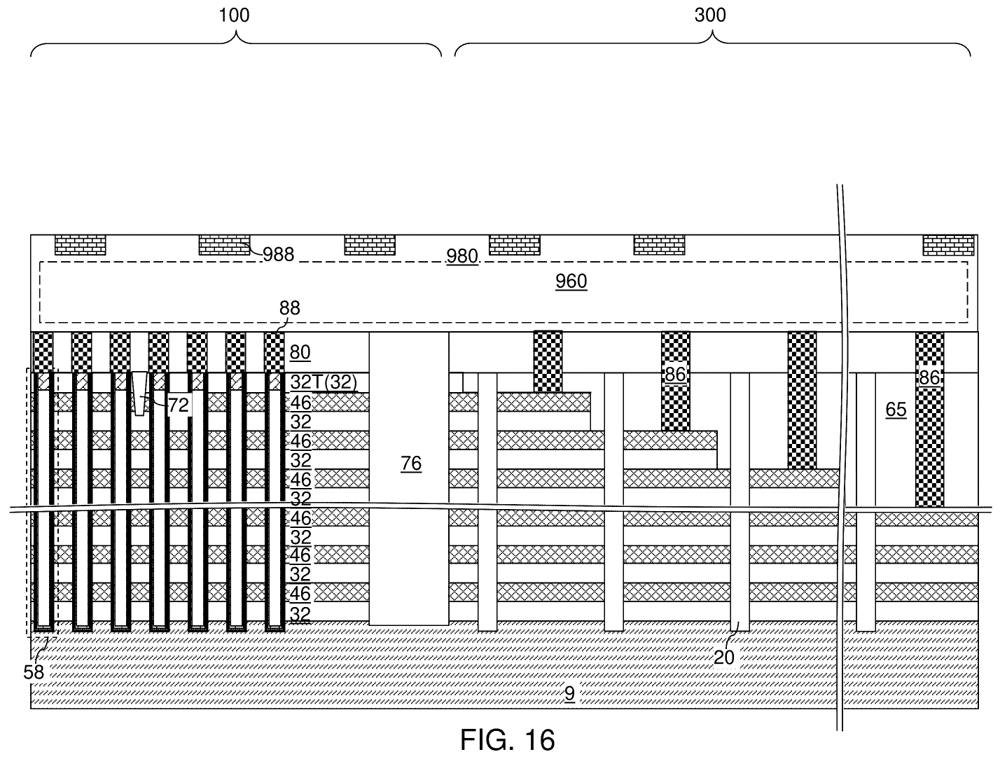

Referring to FIG. 16, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory device comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49; and the drain contact via structures 88 electrically connected to a respective one of the drain regions 63 in the respective memory opening fill structures 58.

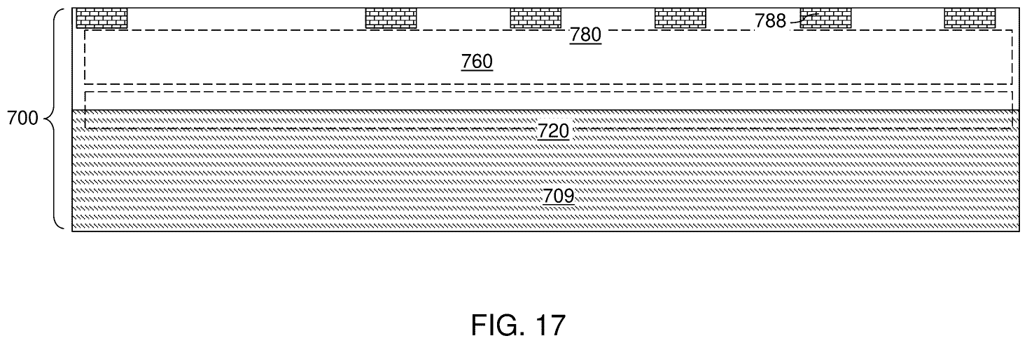

Referring to FIG. 17, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

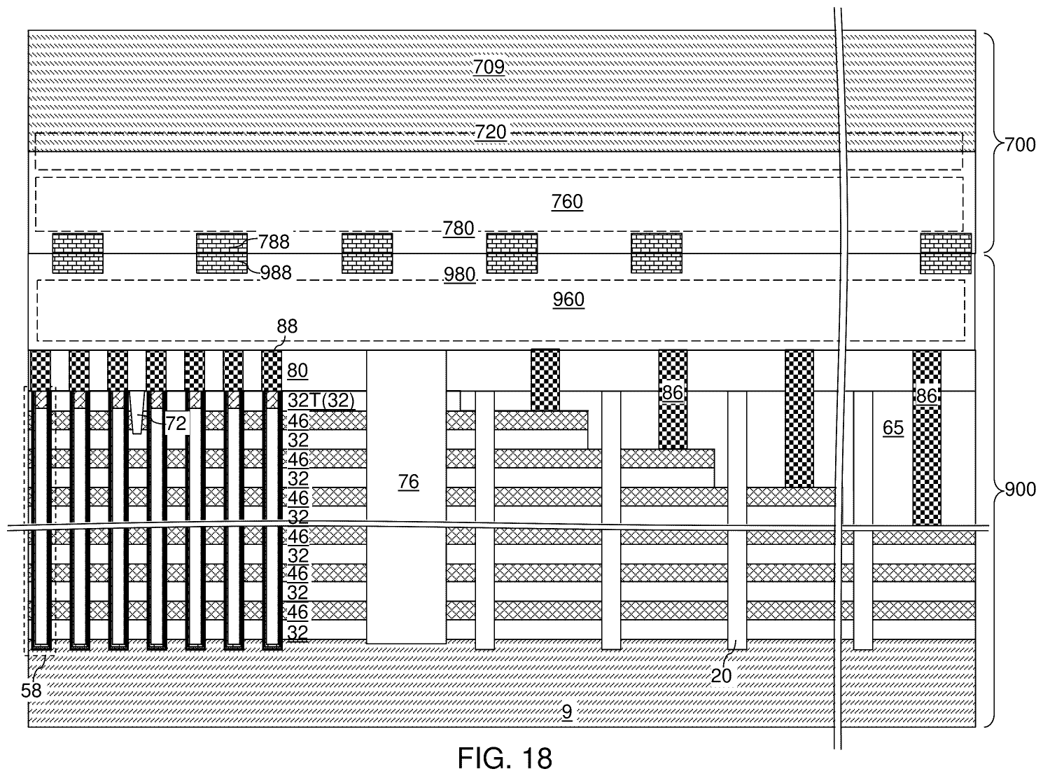

Referring to FIG. 18, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within each respective memory die 900.

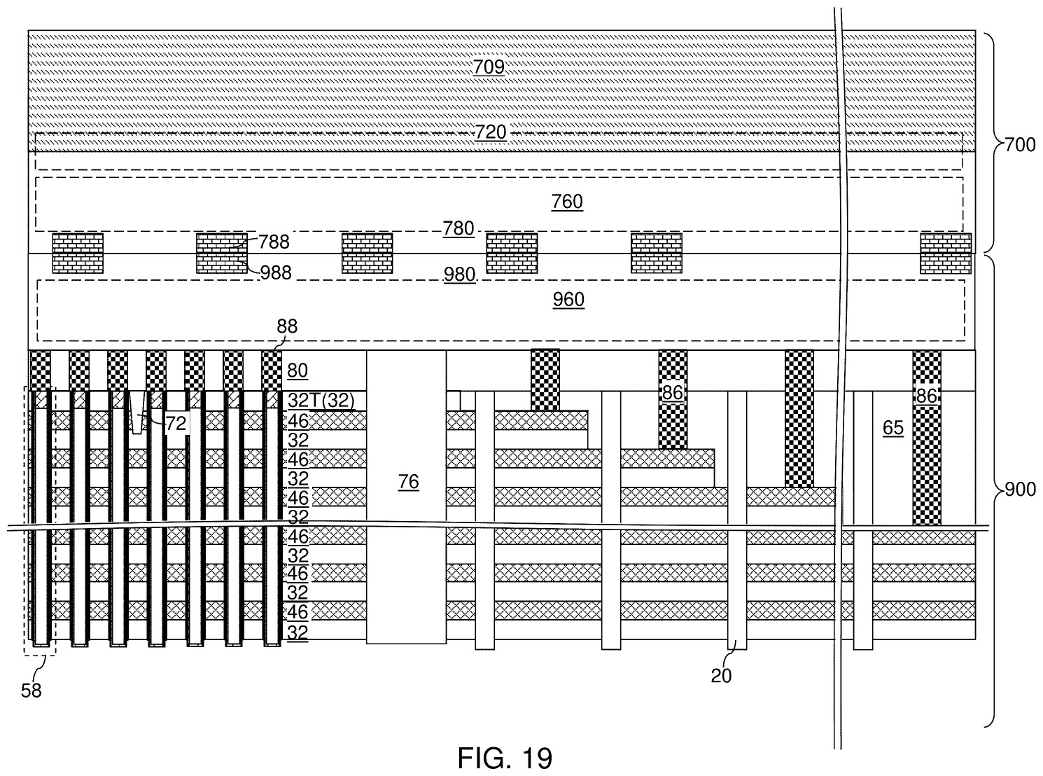

Referring to FIG. 19, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

Referring to FIG. 19, an end portion of each memory film 50 may be removed by performing a sequence of wet etch processes. In one embodiment, the sequence of wet etch processes may comprise a first wet etch process that etches the material of the blocking dielectric layer 52 selective to the material of the charge storage layer 54, a second wet etch process that etches the material of the charge storage layer 54 selective to the material of the tunneling dielectric layer 56, and a third wet etch process that etches the material of the tunneling dielectric layer 56 selective to the material of the vertical semiconductor channel 60. Upon removal of the end portion of the memory film 50, an end portion of each vertical semiconductor channel 60 may be physically exposed.

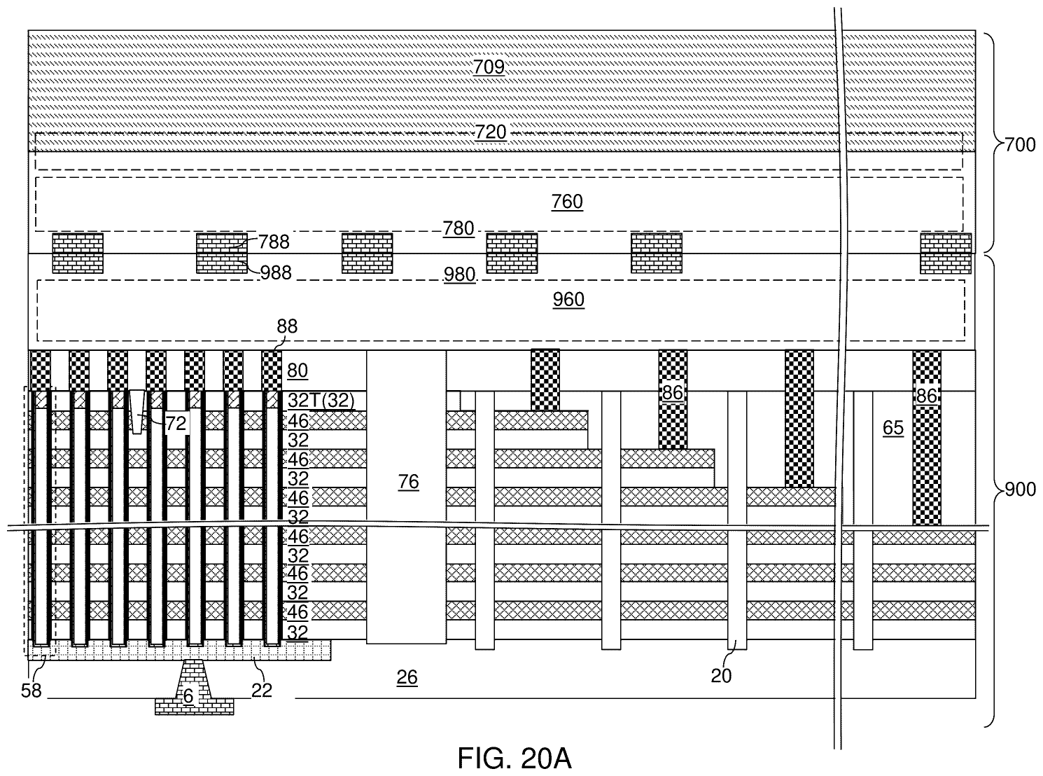

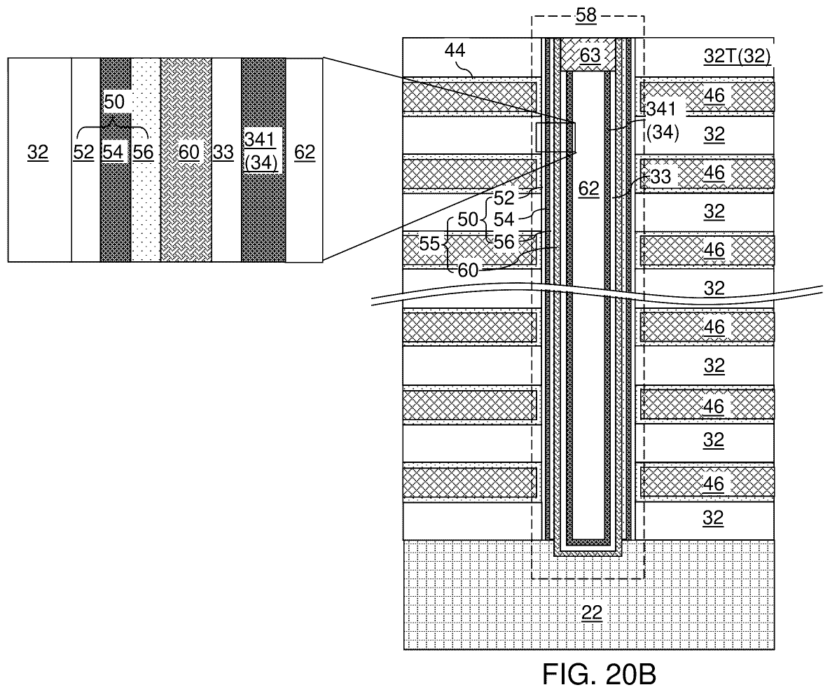

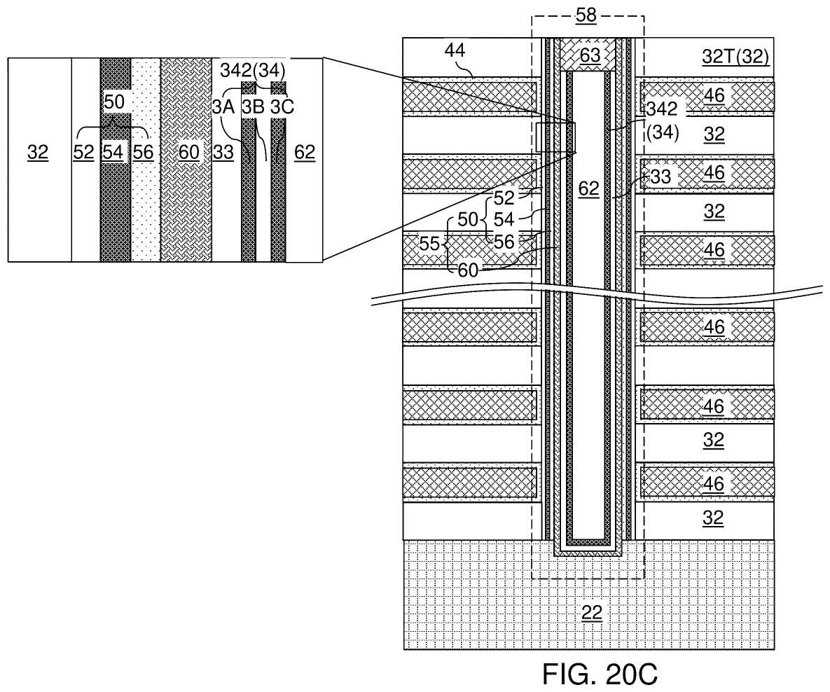

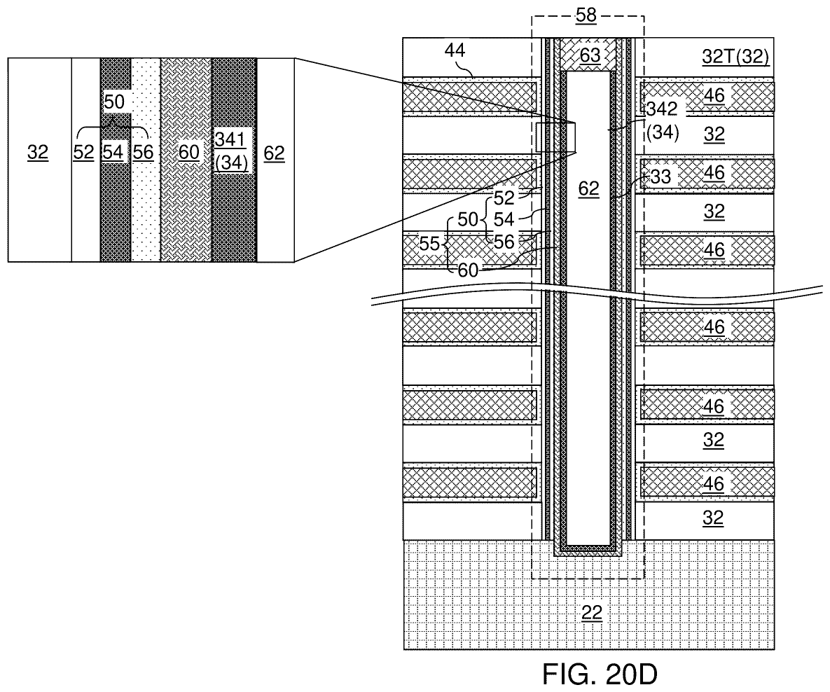

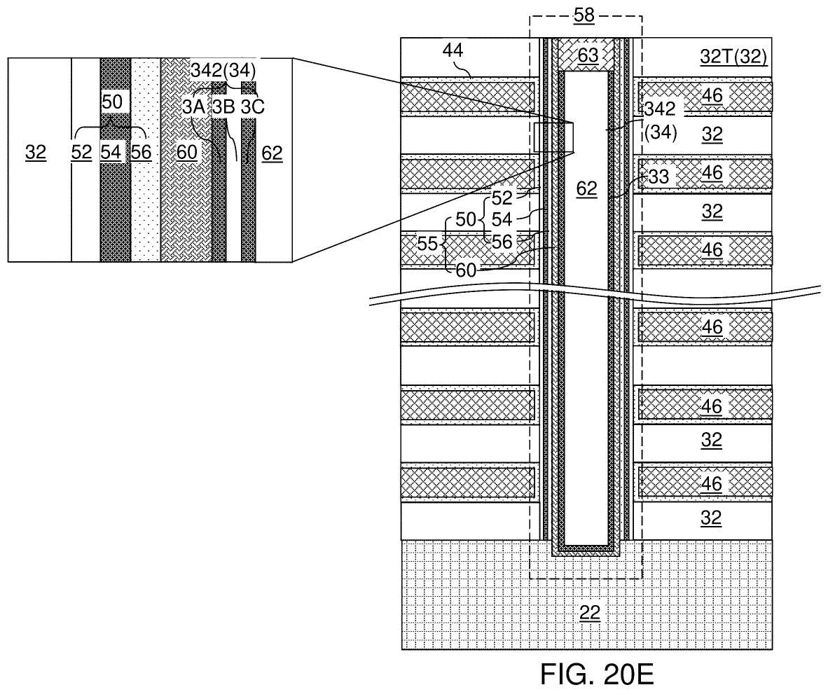

Referring to FIGS. 20A-20E, at least one conductive material can be deposited on the physically exposed surfaces of the bottom portions of the vertical semiconductor channels 60. The at least one conductive material may comprise a doped semiconductor material having a doping of the second conductivity type, and/or at least one metallic material. In one embodiment, the at least one conductive material may comprise doped polysilicon having a doping of the second conductivity type, a metallic barrier material such as TiN, TaN, WN, or MON, and a metal layer having a high electrical conductivity including a metal such as W, Ti, Ta, Cu, Co, Ru, Mo, etc. The at least one conductive material can be patterned to form a source layer 22.

A backside insulating layer 26 can be formed on the backside of the alternating stack (32, 46) and over the source layer 22. Various connection structures such as source contact structures 6 may be formed through the backside insulating layer 26.

FIG. 20B is a magnified vertical cross-sectional view of the first exemplary structure of FIG. 20A around a memory opening fill structure 58 in case the memory opening fill structure 58 has the first configuration of FIG. 7H. FIG. 20C is a magnified vertical cross-sectional view of the first exemplary structure of FIG. 20A around a memory opening fill structure 58 in case the memory opening fill structure 58 has the second configuration of FIG. 8B. FIG. 20D is a magnified vertical cross-sectional view of the first exemplary structure of FIG. 20A around a memory opening fill structure 58 in case the memory opening fill structure 58 has the third configuration of FIG. 9D. FIG. 20E is a magnified vertical cross-sectional view of the first exemplary structure of FIG. 20A around a memory opening fill structure 58 in case the memory opening fill structure 58 has the fourth configuration of FIG. 9E.

Referring to all drawings and according to various embodiments of the present disclosure, a memory device is provided, which comprises: an alternating stack (32, 46) of insulating layers 32 and electrically conductive layers 46; a memory opening 49 vertically extending through the alternating stack (32, 46); and a memory opening fill structure 58 located in the memory opening 49 and comprising, from outside to inside, a memory film 50 containing a vertical stack of memory elements (as embodied as portion of a charge storage layer 54 located at levels of the electrically conductive layers 46), a vertical semiconductor channel 60, a dielectric liner 33, a core-side charge trapping material layer 34, and a dielectric core 62.

In one embodiment, the core-side charge trapping material layer 34 comprises silicon nitride. In one embodiment, the core-side charge trapping material layer 34 comprises aluminum oxide. In one embodiment, the core-side charge trapping material layer 34 comprises silicon oxynitride. In one embodiment, the core-side charge trapping material layer 34 comprises a layer stack comprising a first silicon nitride layer 3A, a second silicon nitride layer 3C, and a silicon oxynitride layer 3B therebetween.

In one embodiment, the dielectric liner 33 comprises a silicon oxide liner in contact with the core-side charge trapping material layer 34 and an inner sidewall of the vertical semiconductor channel 60. In one embodiment, the dielectric core 62 is in direct contact with an inner sidewall of the core-side charge trapping material layer 34.

In one embodiment, the memory film 50 comprises a layer stack that includes a tunneling dielectric layer 56 in contact with an outer sidewall of the vertical semiconductor channel 60, a charge storage layer 54 in contact with an outer sidewall of the tunneling dielectric layer 56, and a blocking dielectric layer 52 in contact with an outer sidewall of the charge storage layer 54. In one embodiment, each of the electrically conductive layers 46 is laterally spaced from the blocking dielectric layer 52 by a respective outer blocking dielectric layer 44 having a respective tubular portion, a respective upper horizontally-extending portion that is adjoined to an upper end of the respective tubular portion, and a respective lower horizontally-extending portion that is adjoined to a lower end of the respective tubular portion. In one embodiment, the memory opening fill structure 58 further comprises a drain region 63 that contacts an annular top surface of the core-side charge trapping material layer 34 and an end portion of the vertical semiconductor channel 60.

In one embodiment, the memory device is erased by applying an erase voltage to the memory device to move emitted electrons from the memory film 50 (e.g., from the charge storage layer 54) and/or from the electrically conductive layers 46 through the vertical semiconductor channel 60 into the core-side charge trapping material layer 34. The erase process may comprise a gate-induced drain leakage (GIDL) process in which holes are injected into the vertical semiconductor channel 60 (e.g., from the source side of the vertical semiconductor channel 60). In one embodiment, the core-side charge trapping material layer 34 is in contact with an inner sidewall of the vertical semiconductor channel 60.

In one embodiment, a pre-conditioning operation may be performed to enhance the stability of trapped electrical charges within the core-side charge trapping material layer 34, thereby improving the overall performance and reliability of the memory device. During the pre-conditioning process, multiple cycles of a combination of a write operation and an erase operation can be performed to stabilize the amount of electrical charges that are trapped within the core-side charge trapping material layer 34. The total number of cycles may be in a range from 10 to 10,000, such as from 30 to 3,000. The pre-conditioning operation ensures a stable baseline level of trapped charges within the core-side charge trapping material layer 34 prior to initial programming or subsequent usage of the memory device. The controlled introduction of charges serves to stabilize the charge trapping dynamics within the core-side charge trapping material layer 34, and to optimize the retention characteristics and mitigating potential fluctuations in device performance over time.

In accordance with various embodiments of the present disclosure, the inclusion of a core-side charge trapping material layer 34 within a memory opening fill structure 58 offers several advantages. The core-side charge trapping material layer 34 enhances overall charge retention capability of the memory device.

Without wishing to be bound by a particular theory, it is believed that trapped electrons in the core-side charge trapping material layer 34 reduce the likelihood of stored electron leakage from the charge storage layer 54 into the vertical semiconductor channel 60 (e.g., due to trap to band tunneling through the tunneling dielectric layer 56) due to the presence of negatively charged electrons in the core-side charge trapping material layer 34. The electrons trapped in the core-side charge trapping material layer 34 increase the neutral threshold voltage of the memory device, which reduces the trap to band tunneling of the electrons through the tunneling dielectric layer 56.

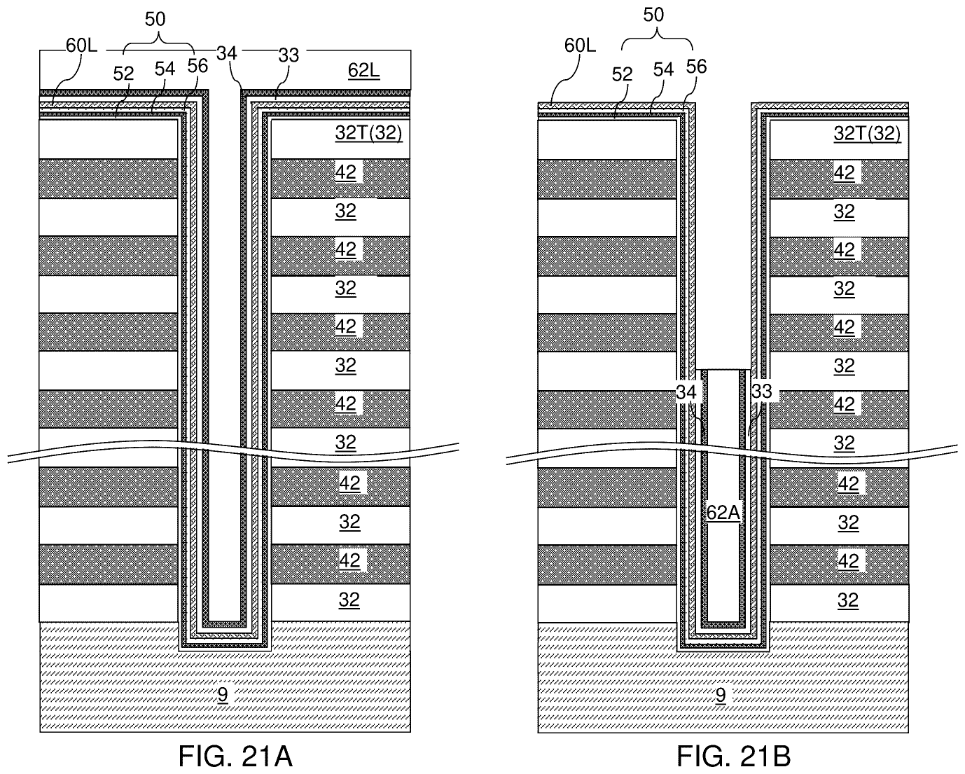

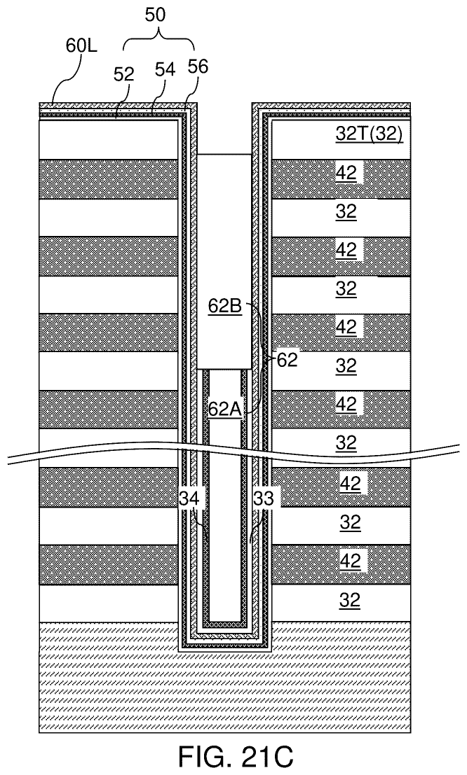

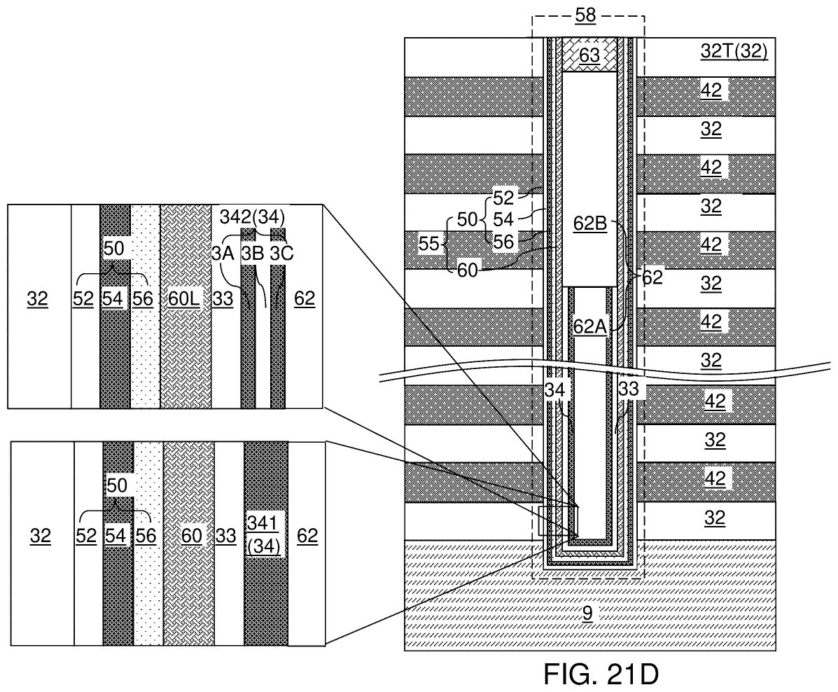

FIGS. 21A-21D are sequential vertical cross-sectional views of a memory opening 49 in a second exemplary structure during formation of a memory opening fill structure 58 in a first configuration according to a second embodiment of the present disclosure.

Referring to FIG. 21A, the first configuration of the second exemplary structure can be derived from any of the first, second, third, and fourth configurations described above. The first configuration of the second exemplary structure in FIG. 21A is illustrated at a processing step that corresponds to the processing steps of FIG. 7E, i.e., after formation of the dielectric core layer 62L. The dielectric core layer 62L comprises a silicon oxide material, such as undoped silicate glass or a doped silicate glass. The configuration for the core-side charge trapping material layer 34 may be any of the configurations for the core-side charge trapping material layer 34 and the optional dielectric liner 33 described with reference to the first, second, third, and fourth configurations described above. As such, a dielectric liner 33 may optionally be present. The core-side charge trapping material layer 34 may comprise a charge trapping dielectric material layer 341 having a homogenous material composition, or may comprise a composite charge trapping dielectric 342 including a layer stack of a plurality of component material layers (3A, 3B, 3C). As discussed above, the core-side charge trapping material layer 34 may comprise at least one material selected from silicon nitride, aluminum oxide, or silicon oxynitride.

Referring to FIG. 21B, at least one timed, selective etch process may be performed to remove portions of the dielectric core layer 62L selectively to the material of the semiconductor channel material layer 60 or selective to the core-side charge trapping material layer 34 from above a horizontal plane that underlies at least the topmost sacrificial material layer 42. The selective etch process may comprise an isotropic etch process (such as a wet etch process) or an anisotropic etch process (such as a reactive ion etch process). For example, if the core-side charge trapping material layer 34 consists of silicon nitride or comprises an innermost layer comprising silicon nitride and if the dielectric core layer 62L comprises a silicon oxide material, a wet etch process employing dilute hydrofluoric acid may be performed to remove an upper portion of the dielectric core layer 62L selective to the core-side charge trapping material layer 34.

Optionally, at least one additional selective etch process can be performed to reduce the vertical extent of the core-side charge trapping material layer 34 and the vertical extent of the optional dielectric liner 33. If a dielectric liner 33 is present, a first selective etch process (e.g., a phosphoric acid etch process) can etch the core-side charge trapping material layer 34 selectively to the material of the dielectric liner 33, and a second selective etch process (e.g., a hydrofluoric acid etch process) can etch the dielectric liner 33 selectively to the material of the semiconductor channel material layer 60L. The first selective etch process and the second selective etch process may comprise wet etch processes. If a dielectric liner 33 is not omitted, a selective etch process (e.g., a phosphoric acid etch process) can etch the core-side charge trapping material layer 34 selectively to the semiconductor channel material layer 60L.

Alternatively, the upper portions of the dielectric core layer 62L, the core-side charge trapping material layer 34 and the optional liner 33 may be removed selective to the semiconductor channel material layer 60L during the same selective etch process.

A remaining portion of the dielectric core layer 62L that underlies the horizontal plane constitutes a primary dielectric core portion 62A. The top surface of the primary dielectric core portion 62A is formed below at least one sacrificial material layer 42.

The at least one selective etch process is timed so that only the upper parts of the dielectric core layer 62L, core-side charge trapping material layer 34 and the optional liner 33 are removed. A total number of sacrificial material layer(s) 42 that overlie the horizontal plane including the top surface of the primary dielectric core portion 62A may be in a range from 1 to 16, such as 1 to 7, although lesser and greater numbers may also be employed. In one embodiment, the horizontal plane including the top surface of the primary dielectric core portion 62A underlies only the topmost sacrificial material layer 42 and overlies all other sacrificial material layers 42. In another embodiment, plural topmost sacrificial material layers 42 are subsequently replaced with a respective drain-select-level electrically conductive layer (i.e., a drain side select gate electrode) that is employed to activate or deactivate a vertical semiconductor channel 60 within a memory opening fill structure 58, and the horizontal plane including the top surface of the primary dielectric core portion 62A underlies each sacrificial material layer 42 that is subsequently replaced with a respective drain-select-level dielectrically conductive layer. In yet another embodiment, at least one sacrificial material layer 42 underlies at least the topmost sacrificial material layer 42 that is subsequently replaced with at least one dummy electrically conductive layer (i.e., dummy word line) that is not employed as an active word line. In this case, the horizontal plane including the top surface of the primary dielectric core portion 62A underlies at least one sacrificial material layer 42 that is subsequently replaced with at least one respective dummy electrically conductive layer. In yet another embodiment, at least one sacrificial material layer 42 underlies all sacrificial material layers 42 that are subsequently replaced with at least one dummy electrically conductive layer (i.e., dummy word line) that is not employed as an active word line. In this case, the horizontal plane including the top surface of the primary dielectric core portion 62A underlies each sacrificial material layer 42 that is subsequently replaced with a respective dummy electrically conductive layer. In other words, the horizontal plane including the top surface of the primary dielectric core portion 62A underlies all drain side select gate electrodes and all dummy word lines, but overlies all active word lines.

The vertical extent of the core-side charge trapping material layer 34 and the vertical extent of the optional dielectric liner 33 (if present) can be reduced at least by a sum of a thickness of one of the insulating layers 32 and a thickness of one of the spacer material layers (such as the sacrificial material layers 42). Specifically, the vertical extent of the core-side charge trapping material layer 34 and the vertical extent of the optional dielectric liner 33 (if present) can be reduced such that topmost surfaces of the remaining portions of the core-side charge trapping material layer 34 and the optional dielectric liner 33 are formed within, or about, the horizontal plane including the top surface of the primary dielectric core portion 62A.

The one or more selective etching steps described above forms an in-process structure comprising a memory film 50 containing a vertical stack of memory elements, a vertical semiconductor channel 60, an optional dielectric liner 33, a core-side charge trapping material layer 34, and a primary dielectric core portion 62A can be formed.

Referring to FIG. 21C, an additional silicon oxide material can be deposited in an upper portion of the void in the memory opening 49 and over the horizontally-extending portion of the semiconductor channel material layer 60L, and can be subsequently vertically recessed. A remaining portion of the additional silicon oxide material constitutes a complementary dielectric core portion 62B. The top surface of the complementary dielectric core portion 62B may be formed at or about the horizontal plane including the bottom surface of the topmost insulating layer 32T. The material of the primary dielectric core portion 62A and the material of the complementary dielectric core portion 62B may be the same, or may be different from each other. The combination of the primary dielectric core portion 62A and the complementary dielectric core portion 62B constitutes a dielectric core 62.

Referring to FIG. 21D, a doped semiconductor material having a doping of a second conductivity type can be formed within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical polishing (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

The drain region 63 can be formed on the complementary dielectric core portion 62B and on an first (i.e., top) end portion of the vertical semiconductor channel 60. The drain region 63 may contact the top end portion of the vertical semiconductor channel 60, and the top end portion of the complementary dielectric core portion 62B. The drain region 63 contacts an annular top surface of the core-side charge trapping material layer 34 and the top end portion of the vertical semiconductor channel 60.

In one embodiment, a memory film 50 may comprise an optional blocking dielectric layer 52, a charge storage layer 54, and an optional tunneling dielectric layer 56. Each contiguous combination of a memory film 50 and a vertical semiconductor channel 60 constitutes a memory stack structure 55. Each combination a memory stack structure 55, a dielectric core 62, the core-side charge trapping material layer 34, an optional dielectric liner 33 and a drain region 63 within a memory opening 49 constitutes a memory opening fill structure 58.

Each memory opening fill structure 58 comprises a respective vertical stack of memory elements, which may comprise portions of the charge storage layer 54 located at levels of the sacrificial material layers 42, or generally speaking, at levels of spacer material layers that may be formed as, or may be subsequently replaced at least partly with, electrically conductive layers.

Referring collectively to FIGS. 21A-21D, a complementary dielectric core portion 62B can be formed on the primary dielectric core portion 62A within a volume of the memory opening 49 that is laterally surrounded by a cylindrical segment of an inner sidewall of the vertical semiconductor channel 60. The dielectric core 62 comprises a primary dielectric core portion 62A that is laterally surrounded by the core-side charge trapping material layer 34, and a complementary dielectric core portion 62B that overlies or underlies the primary dielectric core portion 62A, and is not surrounded by the core-side charge trapping material layer 34. The memory film 50 comprises a layer stack that comprises a tunneling dielectric layer 56 in contact with an outer sidewall of the vertical semiconductor channel 60, a charge storage layer 54 in contact with an outer sidewall of the tunneling dielectric layer 56, and a blocking dielectric layer 52 in contact with an outer sidewall of the charge storage layer 54.

In this embodiment, the core-side charge trapping material layer 34 does not extend through each sacrificial material layer 42 within the alternating stack (32, 42). The core-side charge trapping material layer 34 vertically extends through a first subset of the sacrificial material layers 42 and does not vertically extend through a second subset of the sacrificial material layers 42. In one embodiment, the second subset of the sacrificial material layers 42 comprises a topmost sacrificial material layer 42 of the sacrificial material layers 42. In one embodiment, the second subset of the sacrificial material layers 42 comprises at least two drain-select-level sacrificial material layers 42. In one embodiment, the second subset of the sacrificial material layers 42 comprises sacrificial material layers 42 that are replace with the drain-select-level sacrificial material layers 42 and at least one (or all) of the dummy word lines.

In one embodiment, the core-side charge trapping material layer 34 comprises at least one material selected from silicon nitride, aluminum oxide, or silicon oxynitride. In one embodiment, the core-side charge trapping material layer 34 comprises a layer stack including a first silicon nitride layer 3A, a second silicon nitride layer 3C, and a silicon oxynitride layer 3B located between the first and the second silicon nitride layers. In one embodiment, the dielectric liner 33 is present between and in contact with the core-side charge trapping material layer 34 and an inner sidewall of the vertical semiconductor channel 60.

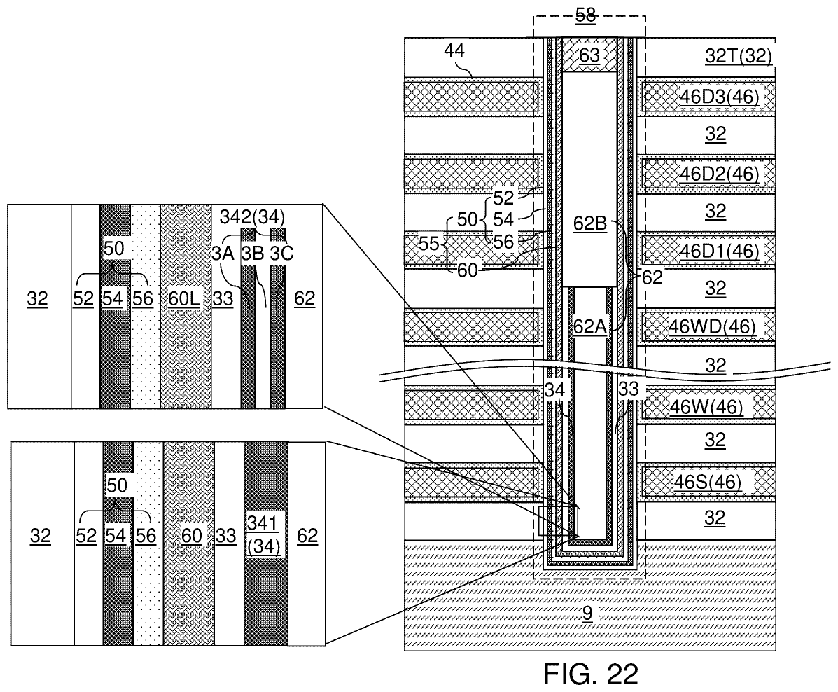

Referring to FIG. 22, the processing steps described with reference to FIGS. 11A-14B can be performed to replace the sacrificial material layers 42 with combinations of a respective outer blocking dielectric layers 44 and a respective electrically conductive layers 46. The electrically conductive layers 46 include at least one drain-side electrically conductive layer (46D1, 46D2, 46D3) that includes at least a topmost electrically conductive layer (such as a first drain-side electrically conductive layer 46D1) is formed above the horizontal plane including an interface between the primary dielectric core portion 62A and the complementary dielectric core portion 62B and/or an annular end surface of the core-side charge trapping material layer 34. In the illustrative example, the at least one drain-side electrically conductive layer (46D1, 46D2, 46D3) comprises the first drain-side electrically conductive layer 46D1, a second drain-side electrically conductive layer 46D2, and a third drain-side electrically conductive layer 46D3. In some embodiments, the at least one drain-side electrically conductive layer (46D1, 46D2, 46D3) may comprise one or more drain side select gate electrodes (e.g., SDDT and SGD) which are used activate or deactivate a vertical semiconductor channel 60 from the drain 63 side.

In some embodiments, the electrically conductive layers 46 may also include at least one dummy word line 46WD, which functions as a passive word line (i.e., an unselected word line) during operation of the three-dimensional memory array without store electrical charge (e.g., electrodes) within an adjacent portion of the charge storage layer 54.

The electrically conductive layers 46 further comprise word lines 46W located between the drain side select gate electrodes (46D1-46D3) and at least one side select gate electrode 46S in the vertical direction. The word lines 46W may be located between the at least one dummy word line 46WD and the at least one source side select gate electrode 46S, and the at least one dummy word line 46WD is located between the drain side select gate electrodes (46D1-46D3) and the word lines 46W in the vertical direction.

Subsequently, the processing steps described with reference to FIGS. 15A-20E can be performed. The first configuration of the exemplary structure comprises memory opening fill structures 58 located in memory openings 49. Each memory opening fill structure 58 comprises, from outside to inside, a memory film 50 containing a vertical stack of memory elements, a vertical semiconductor channel 60, an optional dielectric liner 33, a core-side charge trapping material layer 34 that vertically extends through a first subset (e.g., at least through the word lines 46W) of the electrically conductive layers 46 and does not vertically extend through a second subset (e.g., at least through at least one drain side select gate electrode 46D3 and optionally through at least one dummy word line 46WD) of the electrically conductive layers 46, and a dielectric core 62.

In one embodiment, the second subset of the electrically conductive layers 46 comprises a topmost electrically conductive layer (such as the drain-side electrically conductive layer 46D3) of the electrically conductive layers 46. In one embodiment, the second subset of the electrically conductive layers 46 comprises at least two drain side select gate electrodes 46D2 and 46D3. In one embodiment, the second subset of the electrically conductive layers 46 comprises all of the drain side select gate electrodes 46D1, 46D2 and 46D3.

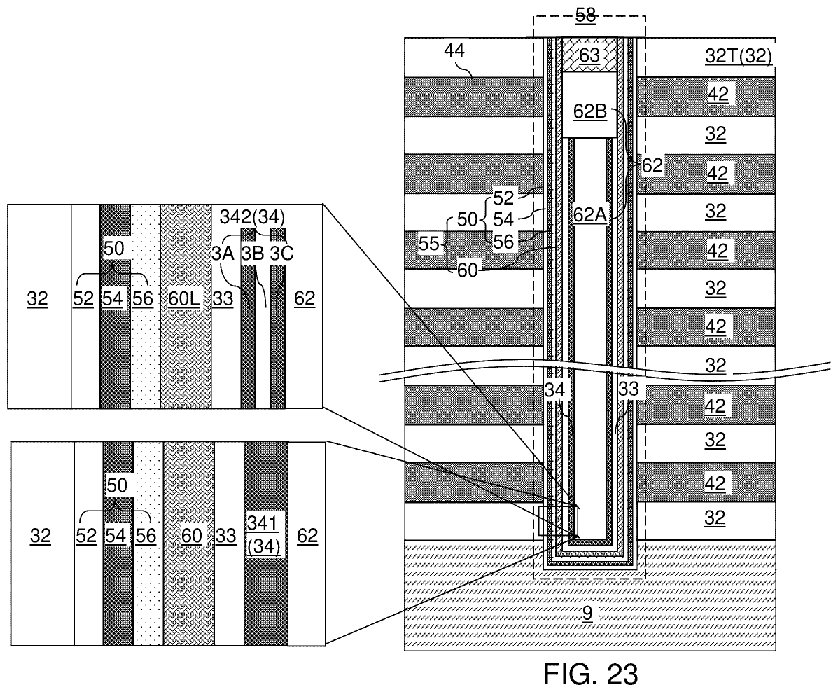

Referring to FIG. 23, a memory opening 49 in a second configuration of the second exemplary structure is illustrated after formation of a memory opening fill structure 58. In the second configuration of the second exemplary structure, the horizontal plane including an interface between the primary dielectric core portion 62A and the complementary dielectric core portion 62B and/or an annular end surface of the core-side charge trapping material layer 34 can be formed below the bottom surface of the topmost sacrificial material layer 42 and above the top surface of the second-from-the-top sacrificial material layer 42.

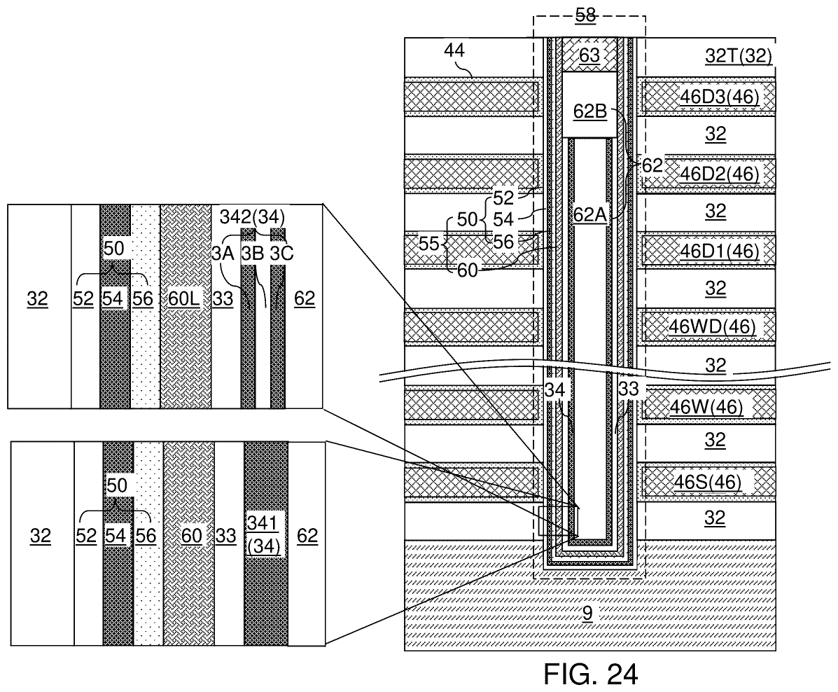

Referring to FIG. 24, the processing steps described with reference to FIGS. 11A-20E can be performed. The sacrificial material layers 42 with combinations of a respective outer blocking dielectric layers 44 and a respective electrically conductive layers 46. In this configuration, the second subset of the electrically conductive layers 46 comprises a topmost electrically conductive layer 46 (such as the topmost drain side select gate electrode 46D3 (i.e., SGDT)) of the electrically conductive layers 46.

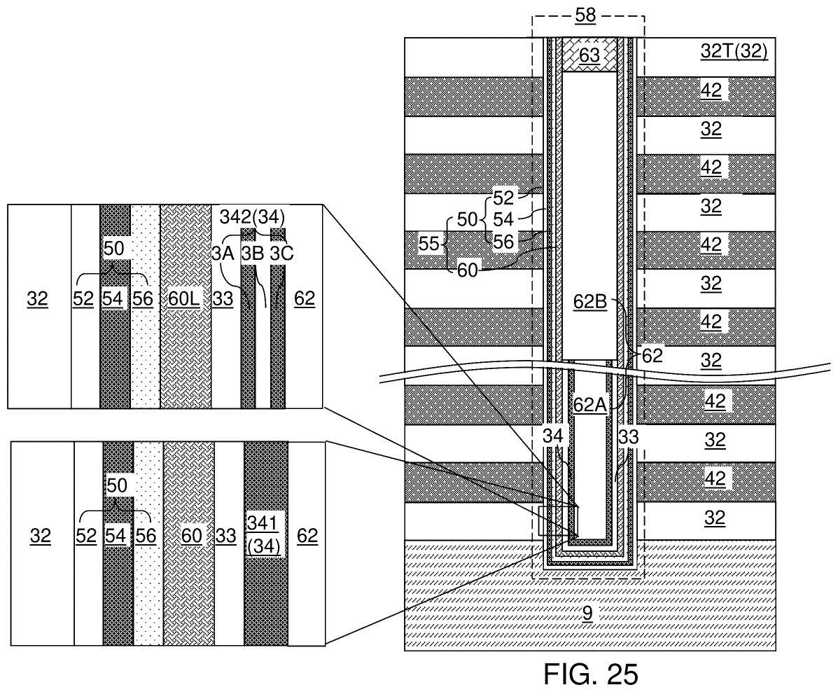

Referring to FIG. 25, a memory opening 49 in a third configuration of the second exemplary structure is illustrated after formation of a memory opening fill structure 58. In the third configuration of the second exemplary structure, the horizontal plane including an interface between the primary dielectric core portion 62A and the complementary dielectric core portion 62B and/or an annular end surface of the core-side charge trapping material layer 34 can be formed below the bottom surface of a sacrificial material layer 42 that is subsequently replaced with a dummy word line.

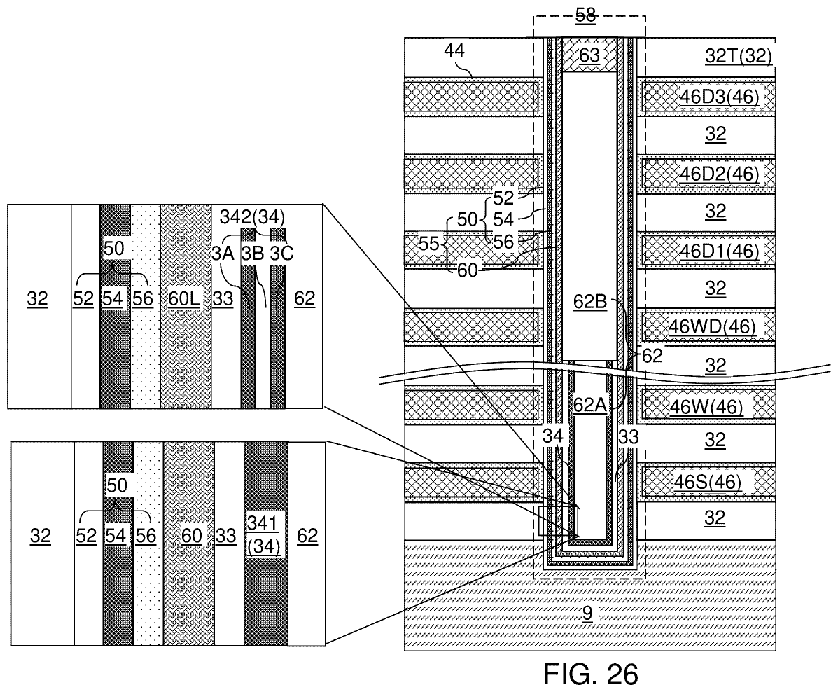

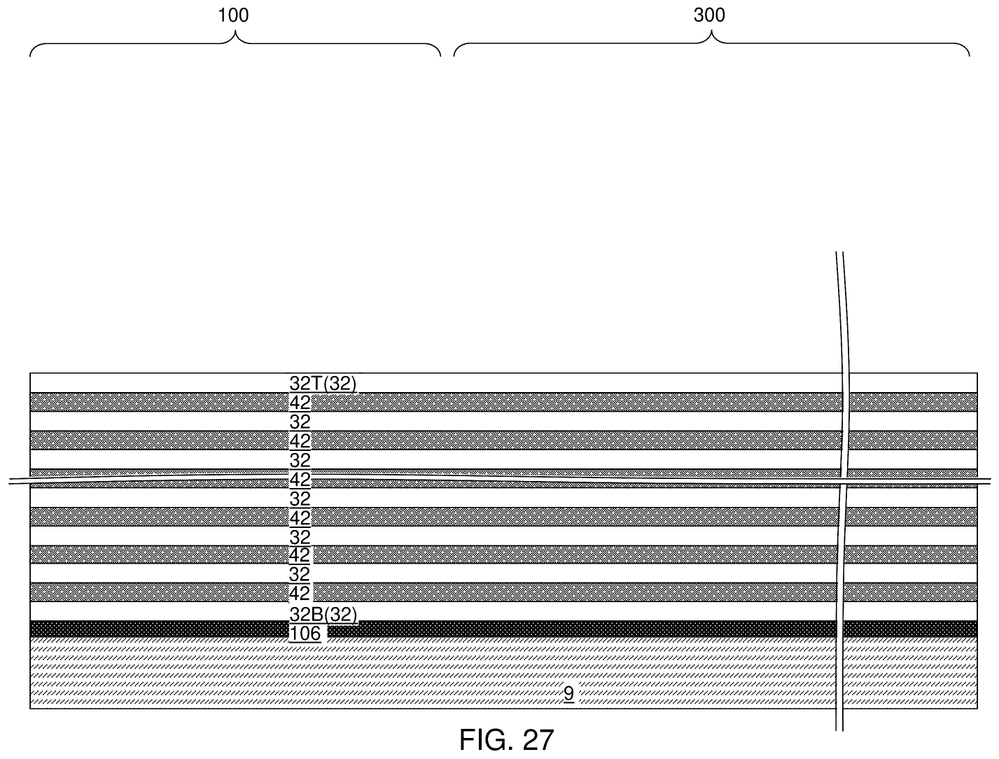

Referring to FIG. 26, the processing steps described with reference to FIGS. 11A-20E can be performed. The sacrificial material layers 42 with combinations of a respective outer blocking dielectric layers 44 and a respective electrically conductive layers 46. In this configuration, the second subset of the electrically conductive layers 46 comprises all of the drain side select gate electrodes (46D1-46D3) and at least of (or all of) the dummy word lines 46WD.

Referring to FIG. 27, a third exemplary structure is illustrated after formation of an alternating stack of insulating layers 32 and sacrificial material layers 42 according to an embodiment of the present disclosure. The third exemplary structure illustrated in FIG. 27 can be derived from the first exemplary structure illustrated in FIG. 1 by forming an etch-stop material layer 106 on a top surface of the carrier substrate 9 prior to formation of the alternating stack (32, 42) of insulating layers 32 and sacrificial material layers 42. The etch-stop material layer 106 may comprise any material that can be employed as an etch-stop material during subsequent removal of the carrier substrate 9. For example, the etch-stop material layer 106 may comprise a dielectric metal oxide, silicon oxycarbide, silicon carbide, silicon carbonitride, etc. The thickness of the etch-stop material layer 106 may be in a range from 10 nm to 300 nm, although lesser and greater thicknesses may also be employed.

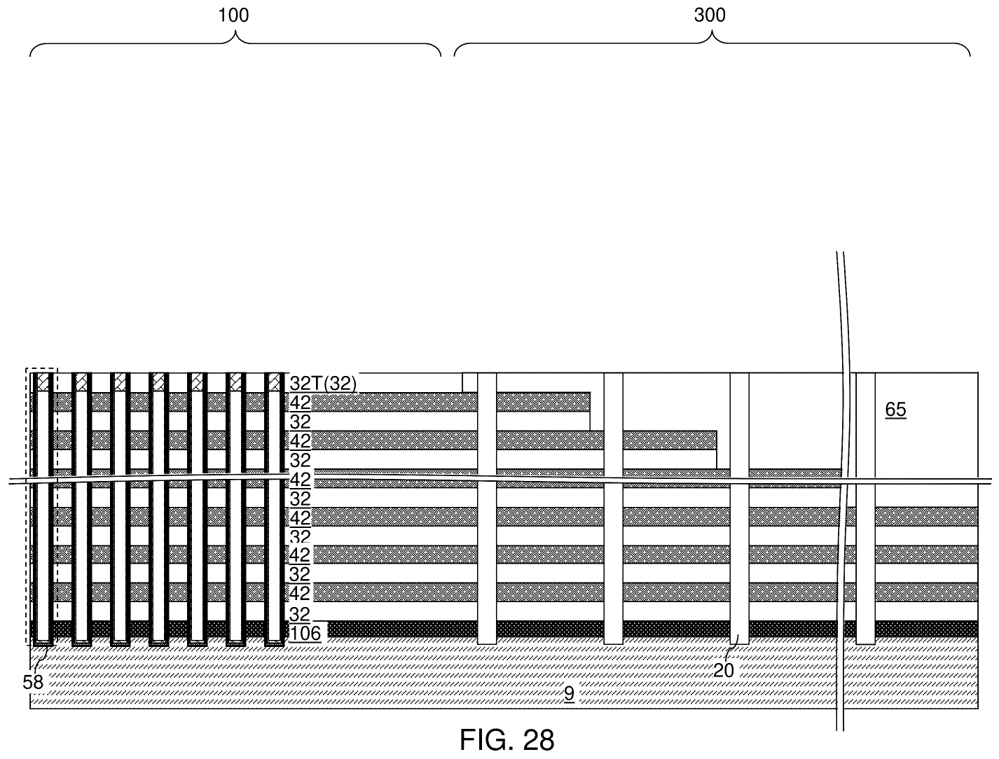

Referring to FIG. 28, the processing steps described with reference to FIGS. 2-9E or the processing steps described with reference to FIGS. 21A-21D, 23, or 25 may be performed to form support pillar structures 20 in the support openings 19 and to form memory opening fill structures 58 in the memory openings 49. The configuration of the memory opening fill structures 58 may be any of the configurations described above with reference to FIGS. 7A-9E, 21A-21D, 23, and 25. If a configuration of the memory opening fill structures 58 described above with reference to FIGS. 7A-9E is employed, the dielectric core 62 is subsequently modified, and as such, is referred to as a primary dielectric core portion 62A.

In summary, a memory film 50 containing a vertical stack of memory elements, a vertical semiconductor channel 60, a core-side charge trapping material layer 34, and a primary dielectric core portion 62A can be formed in each memory opening 49. The primary dielectric core portion 62A after the processing steps of FIG. 28 in the third exemplary structure may have the configurations of a dielectric core 62 in the first exemplary structure or may be the same as a primary dielectric core portion 62A in the second exemplary structure. The core-side charge trapping material layer 34 comprises at least one material selected from silicon nitride, aluminum oxide, or silicon oxynitride.

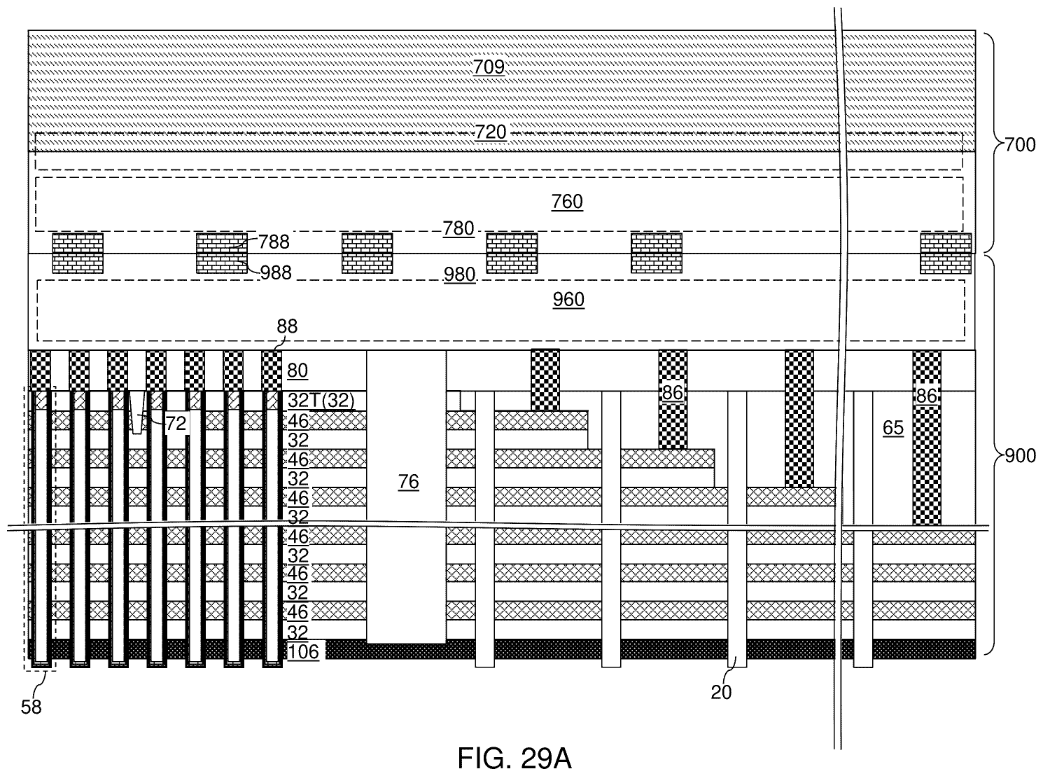

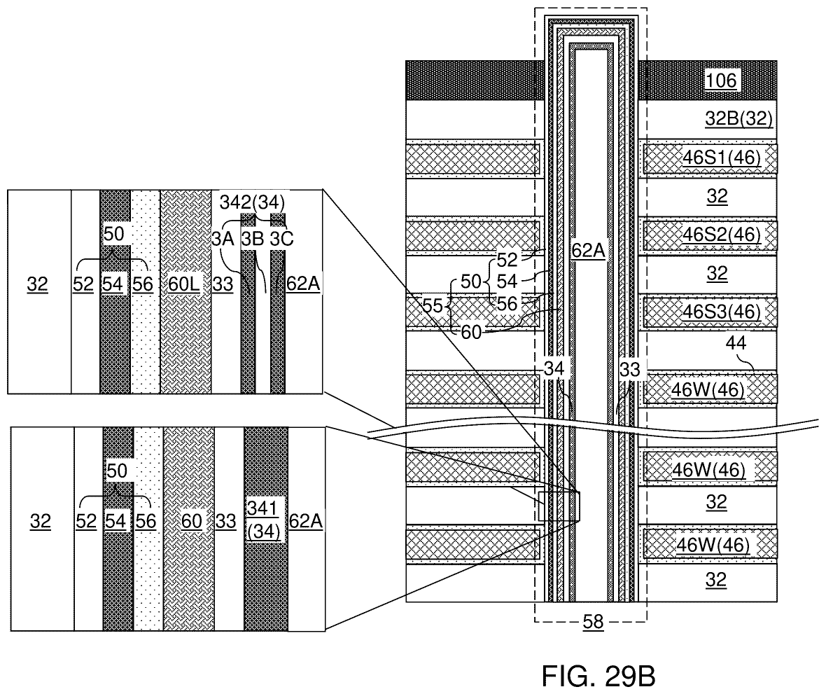

Referring to FIGS. 29A and 29B, the processing steps described with reference to FIGS. 11A-18 can be performed. Subsequently, the carrier substrate 9 can be removed selectively to the etch-stop material layer 106. In this case, a terminal process of a sequence of processing steps that removes the carrier substrate 9 may comprise a selective etch process that removes surface portions of the carrier substrate 9 that are proximal to the etch-stop material layer 106 selective to the material of the etch-stop material layer. For example, the selective etch process may comprise a wet etch process that etches the material of the carrier substrate 9 selective to the material of the etch-stop material layer 106.

The electrically conductive layers 46 may comprise at least one source-side electrically conductive layer (46S1, 46S2, 46S3) that is proximal to the etch-stop material layer 106. The at least one source-side electrically conductive layer (46S1, 46S2, 46S3) includes at least a bottommost electrically conductive layer (such as a first source-side electrically conductive layer 46S1) is most proximal to the etch-stop material layer 106. In the illustrative example, the at least one source-side electrically conductive layer (46S1, 46S2, 46S3) comprises the first source-side electrically conductive layer 46S1, a second source-side electrically conductive layer 46S2, and a third source-side electrically conductive layer 46S3. In some embodiments, one or more of the at least one source-side electrically conductive layer (46S1, 46S2, 46S3) may comprise at least one source side select gate electrode, which can be employed to activate or deactivate a vertical semiconductor channel 60 from the source side.

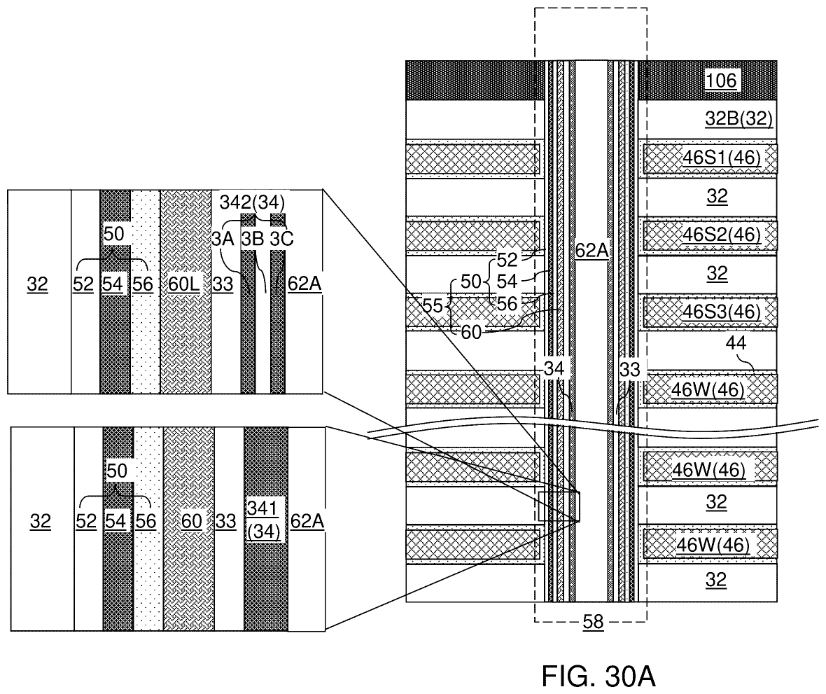

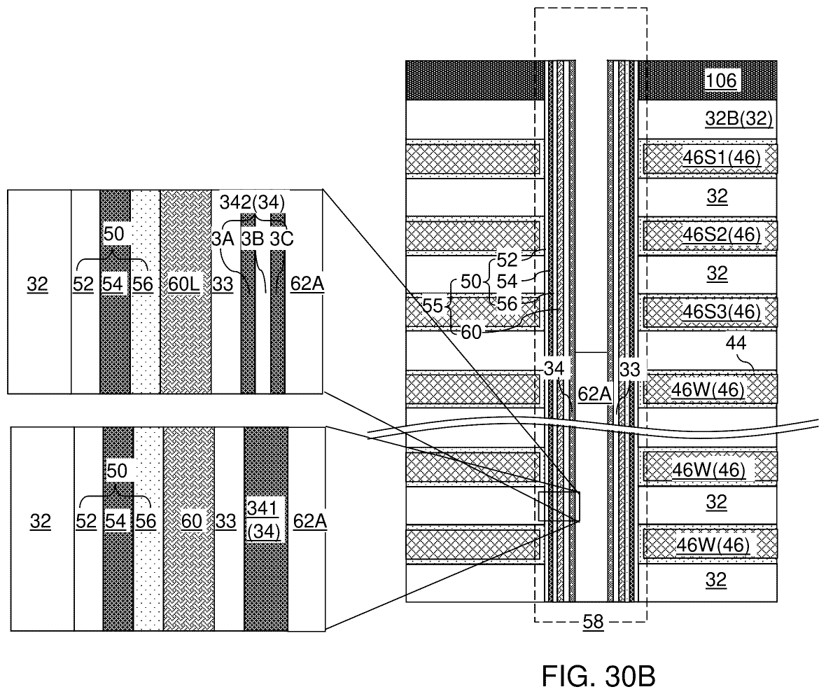

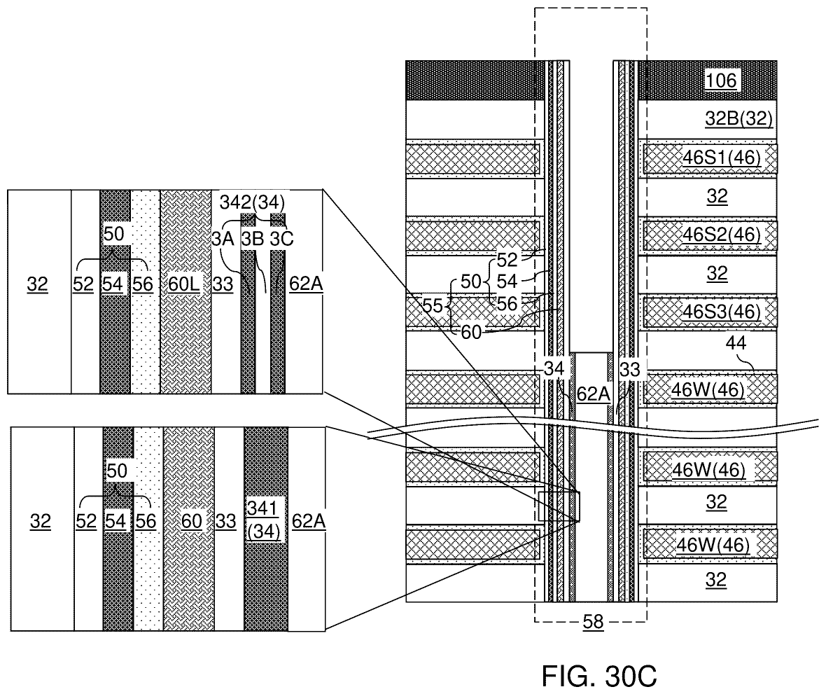

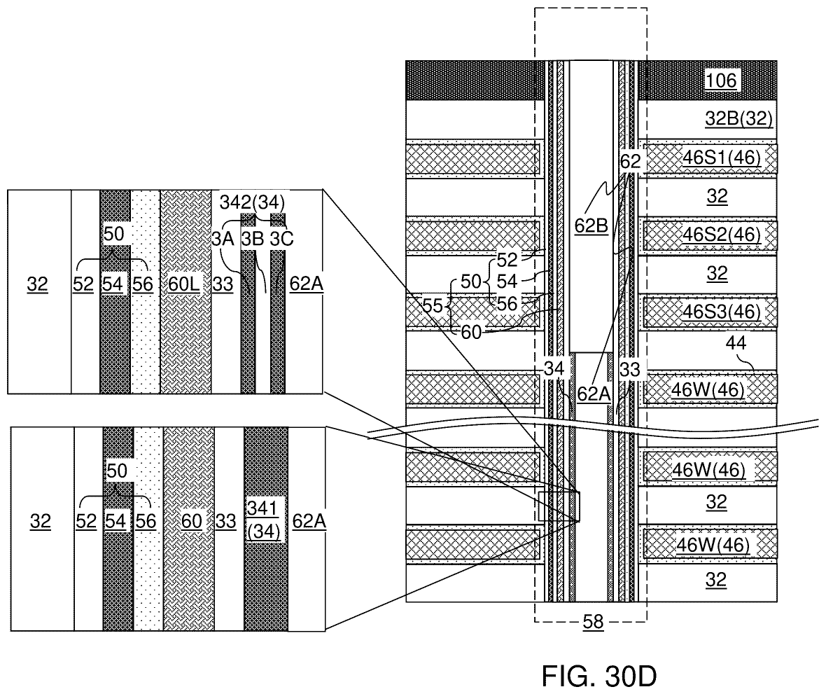

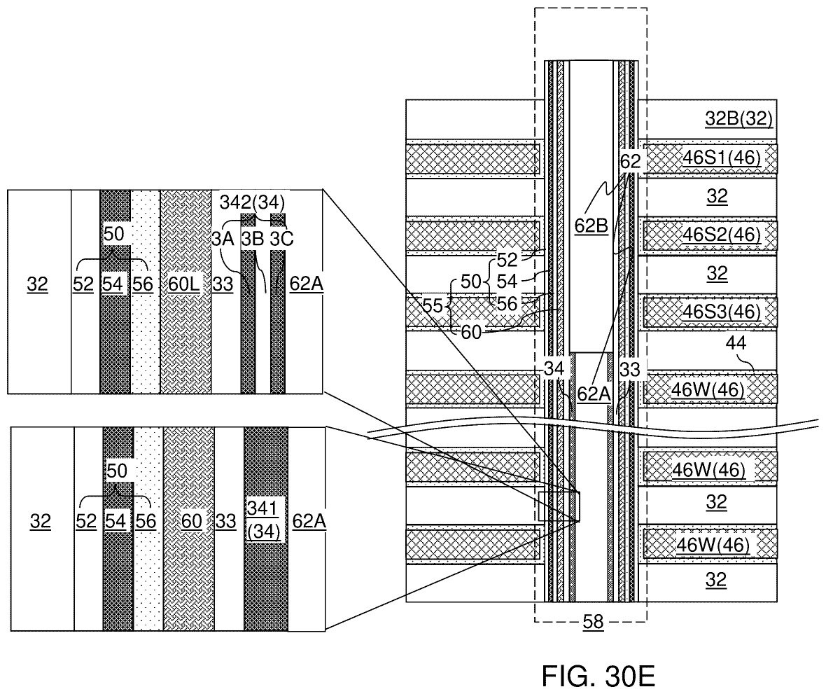

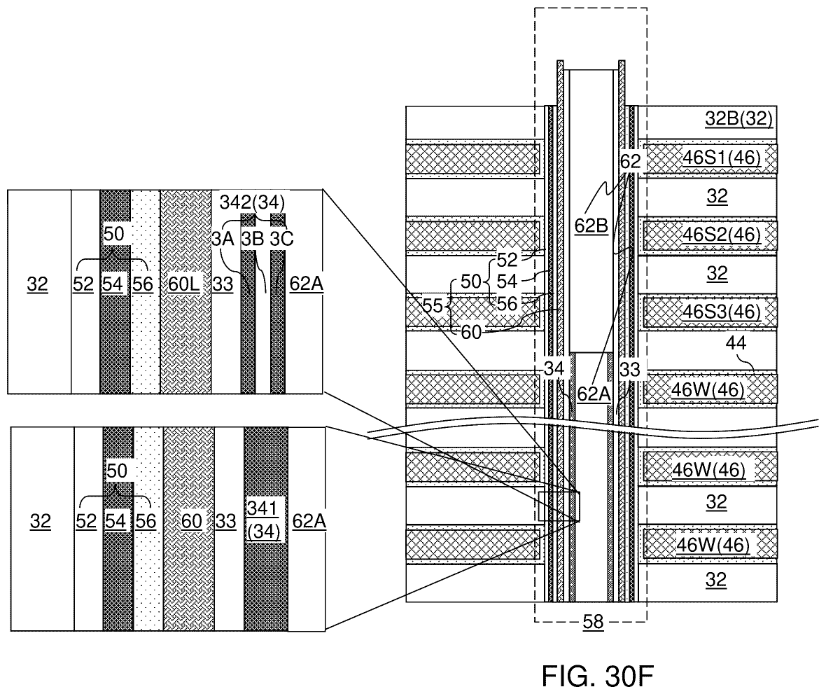

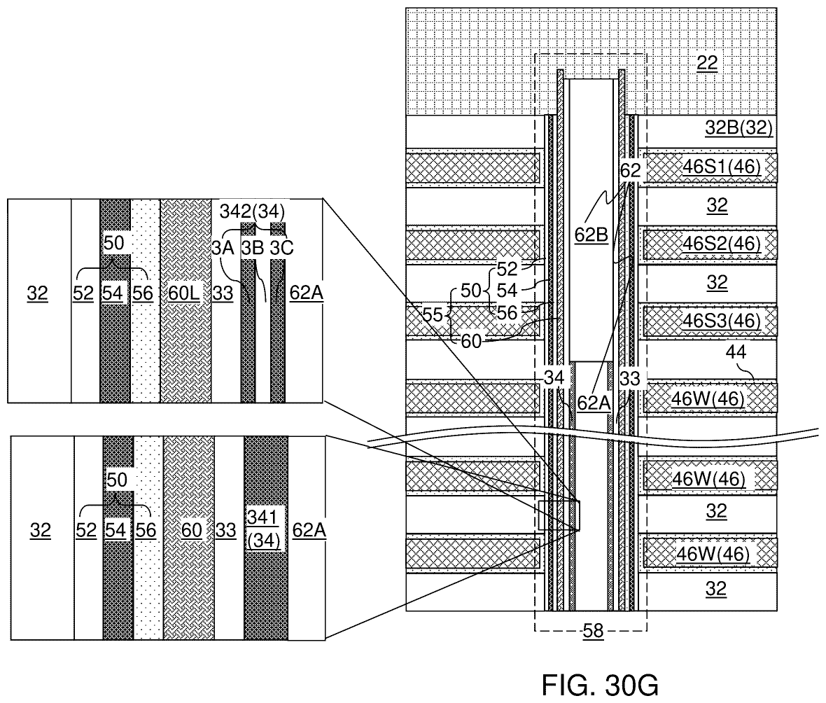

FIGS. 30A-30G are sequential vertical cross-sectional views of a portion of an in-process memory opening fill structure 58 during formation of a complementary dielectric core portion 62B according to an embodiment of the present disclosure. If each memory opening fill structure 58 has a configuration described with reference to 7A-9E, the memory opening fill structure 58 after the processing steps of FIGS. 29A and 29B comprises only a primary dielectric core portion 62A (which is structurally the same as a dielectric core 62 illustrated in FIGS. 7A-9E), and the processing steps of FIGS. 30A-30G form a complementary dielectric core portion 62B. If each memory opening fill structure 58 has a configuration described with reference to 21A-21D, 23, or 25, the memory opening fill structure 58 after the processing steps of FIGS. 29A and 29B comprises a combination of a primary dielectric core portion 62A and complementary dielectric core portion 62B, and the processing steps of FIGS. 30A-30G form an additional complementary dielectric core portion 62B. In this case, a combination of a primary dielectric core portion 62A and two complementary dielectric core portions 62B may be formed, and the complementary dielectric core portion 62B formed at the processing steps of 21A-21D, 23, or 25 is referred to as a first complementary dielectric core portion 62B (or an upper complementary dielectric core portion), and the complementary dielectric core portion 62B formed at the processing steps of FIGS. 30A-30G is referred to as a second complementary dielectric core portion 62B (or a lower complementary dielectric core portion).

Referring to FIG. 30A, a planarization or a recess etch process may be performed to remove portions of the memory opening fill structures 58 that protrude outward from the horizontal plane including a physically exposed planar surface of the etch-stop material layer 106. In one embodiment, a chemical mechanical polishing process may be performed to remove portions of the memory opening fill structures 58 that protrude outward from the horizontal plane including a physically exposed planar surface of the etch-stop material layer 106. A surface of a remaining portion of the primary dielectric core portion 62A can be physically exposed.

Referring to FIG. 30B, a selective etch process can be performed to vertically recess the primary dielectric core portion 62A of each memory opening fill structure 58. A region of each primary dielectric core portion 62A that is proximal to the etch-stop material layer 106 can be removed by the selective etch process. The selective etch process may comprise an anisotropic etch process that etches the material (such as a silicon oxide) of the primary dielectric core portion 62A selective to the materials of the vertical semiconductor channel 60 or the core-side charge trapping material layer 34, as described with respect to the second embodiment above,

Collateral etching of materials of the dielectric liner 33 (if present) and/or any component of the memory film 50 may be minimized due to the lateral masking effect of adjacent material layers (such as the core-side charge trapping material layer 34 and/or the vertical semiconductor channel 60) that are not etched during the selective etch process. A recessed surface of the primary dielectric core portion 62A is vertically spaced from the etch-stop material layer 106 by at least one electrically conductive layer 46 (e.g., by at least the first source-side electrically conductive layer 46S1).

The total number of the electrically conductive layers 46 that is present between the horizontal plane including the recessed surface of the primary dielectric core portion 62A and the etch-stop material layer 106 may be in a range from 1 to 16, such as 2 to 4, although lesser and greater numbers may also be employed. In one embodiment, the horizontal plane including the recessed surface of the primary dielectric core portion 62A is vertically spaced from the etch-stop material layer 106 by no more than one electrically conductive layer 46 (e.g., by the bottom source side elect gate electrode 46S1). In another embodiment, the horizontal plane including the recessed surface of the primary dielectric core portion 62A is vertically spaced from the etch-stop material layer 106 by plural electrically conductive layers 46 (e.g., by two or more, such as all of the source side elect gate electrodes 46S1-46S3).

Referring to FIG. 30C, if the core-side charge trapping material layer 34 is not recessed concurrently with the primary dielectric core portion 62A, then a separate selective etch step may be used to recess the core-side charge trapping material layer 34. A physically exposed annular end surface of the remaining portions of the core-side charge trapping material layer 34 is formed within or about the horizontal plane including the physically exposed recessed surface of the primary dielectric core portion 62A. The selective etch process can etch the core-side charge trapping material layer 34 selectively to the semiconductor channel material layer 60L or selectively to the dielectric liner 33. The selective etch process may comprise a wet etch process, such as a timed phosphoric acid etch process to recess a silicon nitride core-side charge trapping material layer 34.

Generally, a memory film 50 containing a vertical stack of memory elements, a vertical semiconductor channel 60, an optional dielectric liner 33, a core-side charge trapping material layer 34, and a primary dielectric core portion 62A can be formed within each memory opening 49. The vertical extents of the primary dielectric core portion 62A and the core-side charge trapping material layer 34 can be subsequently reduced by performing the processing steps described with reference to 30B and 30C. The core-side charge trapping material layer 34 vertically extends through the first subset of the electrically conductive layers 46 and does not vertically extend through the second subset of the electrically conductive layers 46 described above.

Referring to FIG. 30D, an additional dielectric material, such as a silicon oxide material, can be deposited in the void in the memory opening 49 and on the etch-stop material layer 106. The additional dielectric material can be subsequently planarized, for example, by performing a chemical mechanical polishing (CMP) process. The etch-stop material layer 106 may be employed as a stopper layer for the chemical mechanical polishing process. A remaining portion of the additional dielectric material that fills the void in the memory opening 49 constitutes a complementary dielectric core portion 62B. The physically exposed planar surface of the complementary dielectric core portion 62B may be formed within the horizontal plane including the physically exposed planar surface of the etch-stop material layer 106. The material of the primary dielectric core portion 62A and the material of the complementary dielectric core portion 62B may be the same, or may be different. The combination of the primary dielectric core portion 62A and the complementary dielectric core portion 62B constitutes a dielectric core 62.

If each memory opening fill structure 58 is formed employing a sequence of processing steps described with reference to 7A-9E, the memory opening fill structure 58 after the processing steps of FIG. 30D comprises the primary dielectric core portion 62A (which is structurally the same as a dielectric core 62 illustrated in FIGS. 7A-9E), and the complementary dielectric core portion 62B. If each memory opening fill structure 58 is formed employing a sequence of processing steps described with reference to 21A-21D, 23, or 25, the memory opening fill structure 58 after the processing steps of FIG. 30D comprises a combination of a primary dielectric core portion 62A and two complementary dielectric core portions 62B at either end of the primary dielectric core portion 62A. In this case, the complementary dielectric core portion 62B formed at the processing steps of 21A-21D, 23, or 25 is referred to as a first complementary dielectric core portion 62B (or an upper complementary dielectric core portion), and the complementary dielectric core portion 62B formed at the processing steps of FIGS. 30A-30G is referred to as a second complementary dielectric core portion 62B (or a lower complementary dielectric core portion).

Referring to FIG. 30E, an etch process can be performed to remove the etch-stop material layer 106 selectively to the material of the memory opening fill structures 58 and the bottommost insulating layer 32B. For example, the etch process may comprise a selective reactive ion etch process.

Referring to FIG. 30F, a sequence of selective etch processes can be performed to etch the materials of the blocking dielectric layer 52, the charge storage layer 54, and the tunneling dielectric layer 56. The complementary dielectric core portion 62B and the dielectric liner 33 may be collaterally recessed during the sequence of selective etch processes. A cylindrical surface segment of an outer sidewall of the vertical semiconductor channel 60, a cylindrical surface segment of an inner sidewall of the vertical semiconductor channel 60, and an annular end surface of the vertical semiconductor channel 60 can be physically exposed in each memory opening fill structure 58.

Referring to FIG. 30G, at least one conductive material can be deposited on the physically exposed surfaces of the bottom portions of the vertical semiconductor channels 60. The at least one conductive material may comprise a heavily doped semiconductor material having a doping of the second conductivity type, and/or at least one metallic material. In one embodiment, the at least one conductive material may comprise heavily doped polysilicon having a doping of the second conductivity type, a metallic barrier material such as TiN, TaN, WN, or MON, and a metal layer, such as W, Ti, Ta, Cu, Co, Ru, Mo, etc. The at least one conductive material can be patterned to form a source layer 22.

The source layer 22 can be formed directly on the complementary dielectric core portion 62B and on an end portion of the vertical semiconductor channel 60. In one embodiment, the dielectric core 62 comprises a primary dielectric core portion 62A that is laterally surrounded by the core-side charge trapping material layer 34; and a complementary dielectric core portion 62B that overlies or underlies the primary dielectric core portion 62A (depending on the orientation in which the third exemplary structure is viewed). Generally, a plurality of memory openings 49 vertically extend through the alternating stack (32, 46). A plurality of memory opening fill structures 58 is located in the plurality of memory openings 49. Each of the memory opening fill structures 58 comprises a respective additional memory film 50 and a respective vertical semiconductor channel 60. The source layer 22 may contact each of the plurality of vertical semiconductor channels 60.

The total number of the at least one electrically conductive layer 46 that is present between the source layer 22 and the horizontal plane including the interface between the complementary dielectric core portion 62B and the primary dielectric core portion 62A and/or the core-side charge trapping material layer 34 may be in a range from 1 to 16, although lesser and greater numbers may also be employed.

In one embodiment, the horizontal plane including the interface between the complementary dielectric core portion 62B and the primary dielectric core portion 62A and/or the core-side charge trapping material layer 34 is vertically spaced from the source layer 22 by at least the bottommost electrically conductive layer 46 (i.e., the bottom source side select gate electrode 46S1). For example, the horizontal plane including the interface between the complementary dielectric core portion 62B and the primary dielectric core portion 62A and/or the core-side charge trapping material layer 34 is vertically spaced from the source layer 22 by plural electrically conductive layers 46 (e.g., plural source side select gate electrodes 46S1 and 46S2, or all source side select gate electrodes 46S1-46S3).

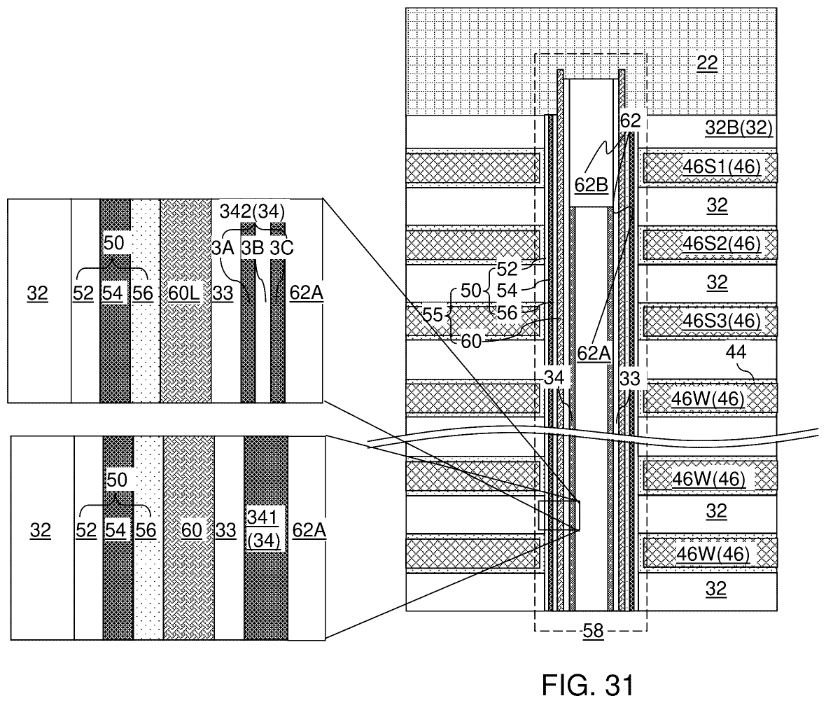

Referring to FIG. 31, a vertical cross-sectional view of a portion of a memory opening fill structure 58 in an alternative configuration of the third exemplary structure is illustrated. In this configuration, the interface between the complementary dielectric core portion 62B (which may be a bottom complementary dielectric core portion 62B in some embodiments) and the primary dielectric core portion 62A and/or the core-side charge trapping material layer 34 can be vertically spaced from the source layer 22 by one the bottommost electrically conductive layer 46 (i.e., the first source side select gate electrode 46S1).

Referring to all drawings and according to various embodiments of the present disclosure, a memory device comprises: an alternating stack (32, 46) of insulating layers 32 and electrically conductive layers 46; a memory opening 49 vertically extending through the alternating stack (32, 46); and a memory opening fill structure 58 located in the memory opening 49 and comprising, from outside to inside, a memory film 50, a vertical semiconductor channel 60, a core-side charge trapping material layer 34 that vertically extends through at least a first subset of the electrically conductive layers 46, and a dielectric core 62.

In one embodiment, the core-side charge trapping material layer 34 does not vertically extend through a second subset of the electrically conductive layers 46.

In the second embodiment, the second subset of the electrically conductive layers 46 comprises a topmost electrically conductive layer 46D3 of the electrically conductive layers 46. In one embodiment, the second subset of the electrically conductive layers 46 comprises at least two drain side select gate electrodes (46D2, 46D3 and optionally 46D1). In one embodiment, the second subset of the electrically conductive layers 46 further comprises at least one dummy word line 46WD, and the first subset of the electrically conductive layers comprises word lines 46W (i.e., active word lines).

In the third embodiment, the second subset of the electrically conductive layers 46 comprises a bottommost electrically conductive layer 46 (such as the first source side select gate electrode 46S1) of the electrically conductive layers 46. In one embodiment, the second subset of the electrically conductive layers 46 comprises at least two source side select gate electrodes (46S1, 46S2 and optionally 46S3).

In the second and third embodiments, the second subset of the electrically conductive layers 46 comprises all source side select gate electrodes (46S1-46S3) and all drain side select gate electrodes (46D1-46D3), and the first subset of the electrically conductive layers comprises active word lines 46W.

In one embodiment, the dielectric core 62 comprises: a primary dielectric core portion 62A that is laterally surrounded by the core-side charge trapping material layer 34: and a complementary dielectric core portion 62B that overlies or underlies the primary dielectric core portion 62A.

In the second embodiment, the memory opening fill structure 58 comprises a drain region 63 contacting a first (i.e., upper) end portion of the vertical semiconductor channel 60; and the complementary dielectric core portion 62B contacts the drain region 63.

In the third embodiment, the memory device further comprises additional memory openings 49 vertically extending through the alternating stack (32, 46): additional memory opening fill structures 58 located in the additional memory openings 49 and comprising a respective additional memory film 50 and a respective additional vertical semiconductor channel 60; and a source layer 22 contacting second (e.g., lower) end portions of the vertical semiconductor channel 60 and the additional vertical semiconductor channels 60. In one embodiment, the complementary dielectric core portion 62B contacts the source layer 22.

In one embodiment, the dielectric core comprises silicon oxide and the core-side charge trapping material layer 34 comprises silicon nitride, aluminum oxide, or silicon oxynitride. In another embodiment, the core-side charge trapping material layer 34 comprises a layer stack including a first silicon nitride layer 3A, a second silicon nitride layer 3C, and a silicon oxynitride layer 3B located between the first and the second silicon nitride layers. In one embodiment, a dielectric liner 33 is located between the core-side charge trapping material layer 34 and the vertical semiconductor channel 60 in the radial direction.

In one embodiment, the memory film 50 comprises a layer stack that comprises a tunneling dielectric layer 56 in contact with an outer sidewall of the vertical semiconductor channel 60, a charge storage layer 54 in contact with an outer sidewall of the tunneling dielectric layer 56, and a blocking dielectric layer 52 in contact with an outer sidewall of the charge storage layer 54.

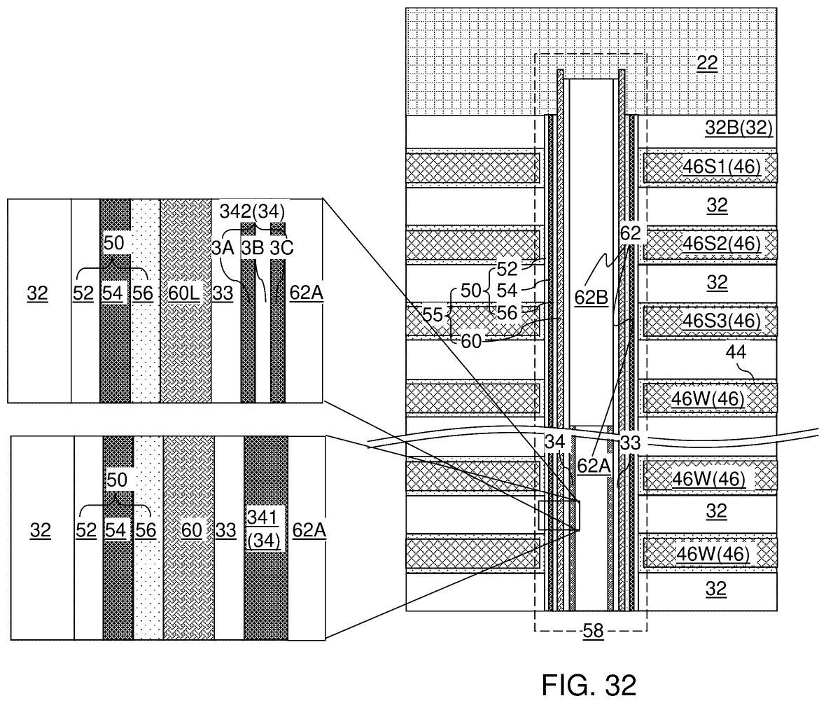

Referring to collectively to the second and third embodiments of FIGS. 21A-32, the reduction in the vertical extent of the core-side charge trapping material layer 34 to remove the portions of the core-side charge trapping material layer 34 located adjacent to the drain and/or source select gate electrodes reduces or eliminates the undesirable threshold voltage shift of the select gate electrodes which may be caused by electrons trapped in the core-side charge trapping material layer 34.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
an alternating stack of insulating layers and electrically conductive layers;
a memory opening vertically extending through the alternating stack; and
a memory opening fill structure located in the memory opening and comprising, from outside to inside, a memory film, a vertical semiconductor channel, a core-side charge trapping material layer that vertically extends through at least a first subset of the electrically conductive layers, and a dielectric core.

2. The memory device of claim 1, wherein the core-side charge trapping material layer does not vertically extend through a second subset of the electrically conductive layers.

3. The memory device of claim 2, wherein the second subset of the electrically conductive layers comprises a topmost electrically conductive layer of the electrically conductive layers.

4. The memory device of claim 3, wherein the second subset of the electrically conductive layers comprises at least two drain side select gate electrodes.

5. The memory device of claim 4, wherein the second subset of the electrically conductive layers further comprises at least one dummy word line, and the first subset of the electrically conductive layers comprises word lines.

6. The memory device of claim 2, wherein the second subset of the electrically conductive layers comprises a bottommost electrically conductive layer of the electrically conductive layers.

7. The memory device of claim 2, wherein the second subset of the electrically conductive layers comprises at least two source side select gate electrodes.

8. The memory device of claim 2, wherein the second subset of the electrically conductive layers comprises all source side select gate electrodes and all drain side select gate electrodes, and the first subset of the electrically conductive layers comprises active word lines.

9. The memory device of claim 1, wherein the dielectric core comprises:
a primary dielectric core portion that is laterally surrounded by the core-side charge trapping material layer; and
a complementary dielectric core portion that overlies or underlies the primary dielectric core portion.

10. The memory device of claim 9, wherein:
the memory opening fill structure comprises a drain region contacting a first end portion of the vertical semiconductor channel; and
the complementary dielectric core portion contacts the drain region.

11. The memory device of claim 10, further comprising:
additional memory openings vertically extending through the alternating stack;
additional memory opening fill structures located in the additional memory openings and comprising a respective additional memory film and a respective additional vertical semiconductor channel; and
a source layer contacting second end portions of the vertical semiconductor channel and the additional vertical semiconductor channels.

12. The memory device of claim 11, wherein the complementary dielectric core portion contacts the source layer.

13. The memory device of claim 1, wherein:
the dielectric core comprises silicon oxide; and
the core-side charge trapping material layer comprises silicon nitride, aluminum oxide, or silicon oxynitride.

14. The memory device of claim 1, wherein:
the dielectric core comprises silicon oxide; and
the core-side charge trapping material layer comprises a layer stack including a first silicon nitride layer, a second silicon nitride layer, and a silicon oxynitride layer located between the first and the second silicon nitride layers.

15. The memory device of claim 1, further comprising a dielectric liner located between the core-side charge trapping material layer and the vertical semiconductor channel, wherein:
the memory film comprises a layer stack that comprises a tunneling dielectric layer in contact with an outer sidewall of the vertical semiconductor channel, a charge storage layer in contact with an outer sidewall of the tunneling dielectric layer, and a blocking dielectric layer in contact with an outer sidewall of the charge storage layer.

16. A method of operating the memory device of claim 1, comprising erasing the memory device by applying an erase voltage to the memory device to move electrons from the memory film through the vertical semiconductor channel into the core-side charge trapping material layer.

17. A method of forming a memory device, comprising:
forming an alternating stack of insulating layers and spacer material layers over a substrate, wherein the spacer material layers are formed as or are subsequently replaced with electrically conductive layers;
forming a memory opening through the alternating stack;
forming a memory film, a vertical semiconductor channel, a core-side charge trapping material layer, and a primary dielectric core portion;
reducing vertical extents of the core-side charge trapping material layer and the primary dielectric core portion at least by a sum of a thickness of one of the insulating layers and a thickness of one of the spacer material layers; and
forming a complementary dielectric core portion on the primary dielectric core portion within a volume that is laterally surrounded by a cylindrical segment of an inner sidewall of the vertical semiconductor channel in the memory opening.

18. The method of claim 17, further comprising forming a drain region on the complementary dielectric core portion and on a first end portion of the vertical semiconductor channel.

19. The method of claim 17, further comprising forming a source layer on the complementary dielectric core portion and on a second end portion of the vertical semiconductor channel.

20. The method of claim 17, wherein:
the primary dielectric core comprises silicon oxide;
the complementary dielectric core comprises silicon oxide;
the core-side charge trapping material layer comprises silicon nitride, aluminum oxide, or silicon oxynitride; and
the vertical extent of the core-side charge trapping material layer is reduced such that the core-side charge trapping material layer vertically extends through a first subset of the electrically conductive layers and does not vertically extend through a second subset of the electrically conductive layers.
